(19) United States
(12) Patent Application Publication
(10) Pub. No.: US 2023/0106034 A1
(43) Pub. Date: Apr. 6, 2023

(54) BULK ACOUSTIC WAVE DEVICES WITH GAP FOR IMPROVED PERFORMANCE

(71) Applicant: Skyworks Global Pte. Ltd., Singapore (SG)

(72) Inventors: Kwang Jae Shin, Yongin (KR); Jae Hyung Lee, Seoul (KR); Jong Duk Han, Yongin (KR); Myung Hyun Park, Seongnam-si (KR); Taecheol Shon, Hwaseong (KR); Youngjun Kim, Hwaseong (KR); Yong Woo Jeon, Anseong (KR); Alexandre Augusto Shirakawa, Cardiff by the Sea, CA (US)

(21) Appl. No.: 17/936,734

(22) Filed: Sep. 29, 2022

Related U.S. Application Data
(60) Provisional application No. 63/251,316, filed on Oct. 1, 2021.
(60) Provisional application No. 63/251,259, filed on Oct. 1, 2021.

(51) Int. Cl. H03H 9/02; H03H 9/10; H03H 9/13; H03H 9/17

(52) U.S. Cl. CPC H03H 9/02228; H03H 9/1014; H03H 9/13; H03H 9/17

(57) ABSTRACT

Aspects of this disclosure relate to bulk acoustic wave devices that have a piezoelectric layer between a first electrode and a second electrode and a suspended frame structure that is suspended over a gap. The gap can be between the first electrode and the piezoelectric layer or between the second electrode and the piezoelectric layer. The bulk acoustic wave devices can have an inner raised frame portion inside of the suspended frame. The gap can be disposed between portions of the first and second electrodes that extend past an end of the piezoelectric layer. A conductive material can extend through an opening in a passivation layer at a location directly above the gap.

### CROSS REFERENCE TO PRIORITY APPLICATIONS

This application claims the benefit of priority U.S. Provisional Patent Application No. 63/251,316, filed Oct. 1, 2021 and titled “SUSPENDED FRAME BULK ACOUSTIC WAVE DEVICES,” and also claims the benefit of priority U.S. Provisional Patent Application No. 63/251,259, filed Oct. 1, 2021 and titled “BULK ACOUSTIC WAVE DEVICES WITH GAP FOR IMPROVED PERFORMANCE,” the contents of each of which are hereby incorporated by reference in their entireties herein.

### BACKGROUND

### Field of the Disclosure

Some embodiments disclosed herein relate to acoustic wave devices, such as bulk acoustic wave devices, and to filters that include bulk acoustic wave devices.

### Description of the Related Art

Acoustic wave filters can be implemented in radio frequency electronic systems. For example, filters in a radio frequency front end of a mobile phone can include one or more acoustic wave filters. A plurality of acoustic wave filters can be arranged as a multiplexer. For instance, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. BAW filters can include BAW resonators. In BAW resonators, acoustic waves propagate in a bulk of a piezoelectric layer. Example BAW resonators include film bulk acoustic wave resonators (FBARs) and solidly mounted resonators (SMRs).

Although various BAW devices exist, there remains a need for improved BAW devices and filters.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

In accordance with one aspect of the disclosure, a bulk acoustic wave device can include a first electrode, a second electrode, and a piezoelectric layer between the first electrode and the second electrode. The device can have an active region where the piezoelectric layer overlaps the first electrode and the second electrode. The active region can include a middle area. The device can have a raised frame structure outside the middle area of the active region. The raised frame structure can include a gap between the first electrode and the second electrode so that at least a portion of the raised frame structure is a suspended frame that is suspended over the gap.

The piezoelectric layer can be over the first electrode, the second electrode can be over the piezoelectric layer, and the gap can be between the first electrode and the piezoelectric layer. The piezoelectric layer can be over the first electrode, the second electrode can be over the piezoelectric layer, and the gap can be between the second electrode and the piezoelectric layer. The raised frame structure can include an inner raised frame portion outside the middle area and inside the suspended frame. The suspended frame can have a height that is taller than a height of the inner raised frame portion. The raised frame structure can include a raised frame layer that extends over at least a portion of the gap. The raised frame layer can extend inward of the gap to form at least a portion of the inner raised frame portion of the raised frame structure. The raised frame layer can have a lower acoustic impedance than at least one of the first electrode, the second electrode, and the piezoelectric layer. The bulk acoustic wave device can further include a passivation layer over the first electrode, the second electrode, the piezoelectric layer, and the raised frame structure. A recessed frame region can be between the raised frame structure and the middle area, and the passivation layer can be thinner at the recessed frame region than at the middle area. The bulk acoustic wave device can include a conductive layer disposed over a portion of the passivation layer, and a portion of the conductive layer can extend into an opening in the passivation layer to electrically contact the second electrode. The opening in the passivation layer can be directly over the gap. A portion of the gap can extend laterally outward past an end of the piezoelectric layer. A portion of the gap can extend downward past a lower surface of the piezoelectric layer. A portion of the first electrode can extend laterally past an end of the piezoelectric layer, a portion of the second electrode can extend laterally past the end of the piezoelectric layer, and the gap can be disposed between the portion of the first electrode and the portion of the second electrode. A distance between the portion of the first electrode and the portion of the second electrode can be less than a thickness of the piezoelectric layer.

In accordance with one aspect of the disclosure, a bulk acoustic wave device can include a first electrode, a second electrode, a piezoelectric layer between the first electrode and the second electrode, and a raised frame structure that includes a suspended frame portion over a gap that is between the first electrode and the second electrode and an inner raised frame portion laterally inward of the suspended frame portion.

The raised frame structure can include a raised frame layer between the first electrode and the second electrode. The inner raised frame portion can include a first portion of the raised frame layer that is not over the gap, and the suspended frame portion can include a second portion of the raised frame layer that extends over the gap. The raised frame layer can have a lower acoustic impedance than at least one of the first electrode, the second electrode, and the piezoelectric layer. The bulk acoustic wave device can further include a passivation layer over the first electrode, the second electrode, the piezoelectric layer, and the raised frame structure. The bulk acoustic wave device can further include a conductive layer disposed over a portion of the passivation layer with a portion of the conductive layer extending into an opening in the passivation layer to electrically contact the second electrode. The opening in the passivation layer can be directly over the gap. A portion of the gap can extend laterally outward past an end of the piezoelectric layer. A portion of the first electrode can extend laterally past an end of the piezoelectric layer, a portion of the second electrode can extend laterally past an end of the piezoelectric layer, and the gap can be disposed between the portion of the first electrode and the portion of the second electrode. A distance between the portion of the first electrode and the portion of the second electrode can be less than a thickness of the piezoelectric layer. The bulk acoustic wave device can further include a reflector cavity, and the first electrode can be between the reflector cavity and the piezoelectric layer. The bulk acoustic wave device can include an acoustic Bragg reflector, and the first electrode can be between the acoustic Bragg reflector and the piezoelectric layer.

In accordance with one aspect of the disclosure a filter that includes one or more of the bulk acoustic wave devices disclosed herein. The filter can be at least one of a band pass filter, a band stop filter, a ladder filter, and a lattice filter. A filter that includes one or more bulk acoustic wave devices disclosed herein can form part of at least one of a diplexer, a duplexer, a multiplexer, and a switching multiplexer. A radio frequency module can include an acoustic wave die including at least one filter that includes one or more of the bulk acoustic wave devices disclosed herein, and a radio frequency circuit element coupled to the acoustic wave die. The acoustic wave die and the radio frequency circuit element can be enclosed within a common module package. A wireless communication device can include an acoustic wave filter including one or more of the bulk acoustic wave devices disclosed herein, an antenna operatively coupled to the acoustic wave filter, a radio frequency amplifier operatively coupled to the acoustic wave filter and configured to amplify a radio frequency signal, and a transceiver in communication with the radio frequency amplifier. The wireless communication device can include a baseband processor in communication with the transceiver. The acoustic wave filter can be included in a radio frequency front end. The wireless communication device can be a user equipment.

In accordance with one aspect of the disclosure, a bulk acoustic wave device can include a first electrode, a second electrode, a piezoelectric layer between the first electrode and the second electrode, with a portion of the first electrode extending laterally past an end of the piezoelectric layer, a portion of the second electrode extending laterally past the end of the piezoelectric layer, and a gap disposed between the portion of the first electrode and the portion of the second electrode.

The bulk acoustic wave device can include a suspended frame structure that includes a portion of the gap. The bulk acoustic wave device can include a raised frame structure that includes a suspended frame portion that is suspended over a portion of the gap and an inner raised frame portion that is laterally inward of the suspended frame portion. The raised frame structure can include a raised frame layer between the first electrode and the second electrode. The inner raised frame portion can include a first portion of the raised frame layer that is not over the gap, and the suspended frame portion can include a second portion of the raised frame layer that extends over the gap. The raised frame layer can have a lower acoustic impedance than at least one of the first electrode, the second electrode, and the piezoelectric layer. The suspended frame portion can have a height that is greater than the inner raised frame portion. A distance between the portion of the first electrode that extends laterally past the end of the piezoelectric layer and the portion of the second electrode that extends laterally past the end of the piezoelectric layer can be less than a thickness of the piezoelectric layer. A first portion of the gap can extend over a portion of the top of the piezoelectric layer, and a second portion of the gap can extend along a lateral end of the piezoelectric layer, and a third portion of the gap can extend lower than a bottom of the piezoelectric layer. A first portion of the gap can be between the piezoelectric layer and the second electrode, and a second portion of the gap can extend laterally past the end of the piezoelectric layer. The second electrode can include a first portion that extends along an upper surface of the piezoelectric layer, a second portion that extends away from the first electrode, and a third portion that extends past the upper surface of the piezoelectric layer and towards the first electrode. The bulk acoustic wave device can include a passivation layer over the first electrode, the second electrode, and the piezoelectric layer. The bulk acoustic wave device can include a conductive layer disposed over a portion of the passivation layer, with a portion of the conductive layer extending into an opening in the passivation layer to electrically contact the second electrode. The opening in the passivation layer can be directly over the gap.

In accordance with one aspect of the disclosure, a bulk acoustic wave device can include a first electrode, a second electrode, a piezoelectric layer between the first electrode and the second electrode, a gap between the first electrode and the second electrode, a passivation layer, with the second electrode between the piezoelectric layer and the passivation layer, and a conductive layer, with the passivation layer between a first portion of the conductive layer and the second electrode, and a second portion of the conductive layer extending into an opening in the passivation layer to electrically contact the second electrode. The opening in the passivation layer can be disposed directly above the gap between the first electrode and the second electrode.

The opening in the passivation layer can be disposed directly above the first electrode, the piezoelectric layer, and the second electrode. The bulk acoustic wave device can include an active region where the piezoelectric layer overlaps the first electrode and the second electrode. An end of the upper electrode can define a first end of the active region, and an end of the piezoelectric layer can define a second end of the active region opposite the first end. The bulk acoustic wave device can include a suspended frame structure that includes a portion of the gap. The bulk acoustic wave device can include a raised frame structure that includes a suspended frame portion that is suspended over a portion of the gap and an inner raised frame portion that is laterally inward of the suspended frame portion. The raised frame structure can include a raised frame layer between the first electrode and the second electrode, the inner raised frame portion can include a first portion of the raised frame layer that is not over the gap, and the suspended frame portion can include a second portion of the raised frame layer that extends over the gap. The raised frame layer can have a lower acoustic impedance than at least one of the first electrode, the second electrode, and the piezoelectric layer. The suspended frame portion can have a height that is greater than the inner raised frame portion. A portion of the first electrode can extend laterally past an end of the piezoelectric layer, a portion of the second electrode can extend laterally past the end of the piezoelectric layer, and the gap can be disposed between the portion of the first electrode and the portion of the second electrode. A distance between the portion of the first electrode that extends laterally past the end of the piezoelectric layer and the portion of the second electrode that extends laterally past the end of the piezoelectric layer can be less than a thickness of the piezoelectric layer. A first portion of the gap can extend over a portion of the top of the piezoelectric layer, and a second portion of the gap can extend along a lateral end of the piezoelectric layer, and a third portion of the gap can extend lower than a bottom of the piezoelectric layer. A first portion of the gap can be between the piezoelectric layer and the second electrode, and a second portion of the gap can extend laterally past the end of the piezoelectric layer. The second electrode can include a first portion that extends along an upper surface of the piezoelectric layer, a second portion that extends away from the first electrode, and a third portion that extends past the upper surface of the piezoelectric layer and towards the first electrode. The bulk acoustic wave device can include a reflector cavity, with the first electrode between the reflector cavity and the piezoelectric layer. The bulk acoustic wave device can include an acoustic Bragg reflector, with the first electrode between the acoustic Bragg reflector and the piezoelectric layer.

A filter can include one or more of the bulk acoustic wave devices disclosed herein. The filter can be at least one of a band pass filter, a band stop filter, a ladder filter, and a lattice filter. A filter that includes one or more bulk acoustic wave devices disclosed herein can form part of at least one of a diplexer, a duplexer, a multiplexer, and a switching multiplexer. A radio frequency module can include an acoustic wave die with at least one filter that has one or more of the bulk acoustic wave devices disclosed herein, and a radio frequency circuit element coupled to the acoustic wave die. The acoustic wave die and the radio frequency circuit element can be enclosed within a common module package. A wireless communication device can include an acoustic wave filter including one or more of the bulk acoustic wave devices disclosed herein, an antenna operatively coupled to the acoustic wave filter, a radio frequency amplifier operatively coupled to the acoustic wave filter and configured to amplify a radio frequency signal, and a transceiver in communication with the radio frequency amplifier. The wireless communication device can include a baseband processor in communication with the transceiver. The acoustic wave filter can be included in a radio frequency front end. The wireless communication device can be user equipment.

In accordance with one aspect of the disclosure, a method of making a bulk acoustic wave device can include forming a first electrode over a substrate, forming a piezoelectric layer over the first electrode, forming a sacrificial layer over the piezoelectric layer, forming a second electrode over the sacrificial layer, and removing the sacrificial layer to produce a gap between the first electrode and the second electrode, the gap elevating a portion of the second electrode to provide a suspended frame.

The method can include forming an inner raised frame portion disposed laterally inward of the suspended frame. The suspended frame can be formed with a height that is taller than a height of the inner raised frame. The method can include forming a raised frame layer with a first portion over the piezoelectric layer and not extending over the sacrificial layer and a second portion that extends over the sacrificial layer. The method can include forming a first raised frame layer over the piezoelectric layer, with the second electrode formed over the first raised frame layer. The method can include forming a second raised frame layer over the second electrode. The first raised frame layer can have a lower acoustic impedance than the second raised frame layer. The method can include forming a passivation layer over the second electrode. The method can include forming an opening through the passivation layer and forming a conductive layer over a portion of the passivation layer with a portion of the conductive layer extending into the opening in the passivation layer to electrically contact the second electrode. The opening through the passivation layer can be disposed directly over gap. A portion of the sacrificial layer can be formed extending laterally outward past an end of the piezoelectric layer, and removal of the sacrificial layer can form the gap extending laterally outward past the end of the piezoelectric layer. The method can include forming a cavity sacrificial layer over a portion of the substrate, with the first electrode formed over the cavity sacrificial layer, and the method can include removing the cavity sacrificial layer to produce a cavity between the substrate and the first electrode. The cavity sacrificial layer can be removed to form the cavity at the same time that the sacrificial layer is removed to form the gap.

In accordance with one aspect of the disclosure, a method of making a bulk acoustic wave device can include forming a first electrode over a substrate, forming a piezoelectric layer over the first electrode, with a portion of the first electrode extending past an end of the piezoelectric layer, forming a sacrificial layer over a portion of the piezoelectric layer and over the portion of the lower electrode, forming a second electrode over the sacrificial layer, with a portion of the second electrode extending past the end of the piezoelectric layer, and removing the sacrificial layer to produce a gap between the portion of the first electrode and the portion of the second electrode.

The gap can elevate a portion of the second electrode to provide a suspended frame. The method can include forming an inner raised frame portion disposed laterally inward of the suspended frame. The suspended frame can be formed with a height that is taller than a height of the inner raised frame. The method can include forming a raised frame layer with a first portion over the piezoelectric layer and not extending over the sacrificial layer and a second portion that extends over the sacrificial layer. The method can include forming a first raised frame layer over the piezoelectric layer, with the second electrode formed over the first raised frame layer, and the method can include forming a second raised frame layer over the second electrode. The first raised frame layer can have a lower acoustic impedance than the second raised frame layer. The method can include forming a passivation layer over the second electrode. The method can include forming an opening through the passivation layer and forming a conductive layer over a portion of the passivation layer with a portion of the conductive layer extending into the opening in the passivation layer to electrically contact the second electrode. The opening through the passivation layer can be disposed directly over gap. The method can include forming a cavity sacrificial layer over a portion of the substrate. The first electrode can be formed over the cavity sacrificial layer. The method can include removing the cavity sacrificial layer to produce a cavity between the substrate and the first electrode. The cavity sacrificial layer can be removed to form the cavity at the same time that the sacrificial layer is removed to form the gap.

### BRIEF DESCRIPTION OF THE DRAWINGS

Embodiments of this disclosure will now be described, by way of non-limiting example, with reference to the accompanying drawings, like reference numerals can refer to similar features throughout.

FIG. 1 is a plan view of an example embodiment of a bulk acoustic wave device.

FIG. 2 is a cross-sectional view of an example embodiment of a suspended frame bulk acoustic wave device.

FIG. 3 is a cross-sectional view of another example embodiment of a suspended frame bulk acoustic wave device.

FIG. 3A is a cross-sectional view of another example embodiment of a suspended frame bulk acoustic wave device.

FIG. 3B is a cross-sectional view of another example embodiment of a suspended frame bulk acoustic wave device.

FIG. 4 is a cross-sectional view of an example embodiment of a raised frame bulk acoustic wave device.

FIG. 4A is a cross-sectional view of another example embodiment of a raised frame bulk acoustic wave device.

FIG. 5 is a graph showing experimental data comparing quality factor (Q) values for BAW devices.

FIG. 6 is a graph showing experimental data comparing spurious modes or noise of BAW devices.

FIG. 7 is a graph showing experimental data comparing BAW devices with different electromechanical coupling coefficient (kₜ²) values.

FIG. 8 is a cross-sectional view of another example embodiment of a suspended frame bulk acoustic wave device.

FIG. 9 is a cross-sectional view of another example embodiment of a suspended frame bulk acoustic wave device.

FIG. 9A is a cross-sectional view of another example embodiment of a suspended frame bulk acoustic wave device.

FIG. 9B is a cross-sectional view of another example embodiment of a suspended frame bulk acoustic wave device.

FIG. 10 is a cross-sectional view of another example embodiment of a suspended frame bulk acoustic wave device.

FIG. 11 is a cross-sectional view of another example embodiment of a suspended frame bulk acoustic wave device.

FIG. 12 is a cross-sectional view of another example embodiment of a suspended frame bulk acoustic wave device.

FIG. 12A is a cross-sectional view of another example embodiment of a suspended frame bulk acoustic wave device.

FIG. 12B is a plan view of an example embodiment of a bulk acoustic device.

FIG. 12C shows a cross-section view of an example BAW device.

FIG. 13 is a schematic diagram of an example of an acoustic wave ladder filter.

FIG. 14 is a schematic diagram of an example of a duplexer.

FIG. 15 is a schematic diagram of an example of a multiplexer.

FIG. 16 is a schematic block diagram of a module that includes an antenna switch and duplexers that include one or more raised frame bulk acoustic wave devices.

FIG. 17A is a schematic block diagram of a module that includes a power amplifier, a radio frequency switch, and duplexers that include one or more raised frame bulk acoustic wave devices.

FIG. 17B is a schematic block diagram of a module that includes a low noise amplifier, a radio frequency switch, and acoustic wave filters that include one or more raised frame bulk acoustic wave devices.

FIG. 18 is a schematic block diagram of a module that includes a power amplifier, a radio frequency switch, a duplexer that includes one or more raised frame bulk acoustic wave devices.

FIG. 19A is a schematic block diagram of a wireless communication device that includes filters that include one or more raised frame bulk acoustic wave devices.

FIG. 19B is a schematic block diagram of another wireless communication device that includes filters that include one or more raised frame bulk acoustic wave devices.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The positions and directions described herein may be described in relation to the orientations illustrated in the Figures, and in some cases the illustrated devices could be positioned in different orientations during use. For example, in some instances a substrate is shown at the bottom of a device, and the substrate could still be considered the bottom of the device even if it were installed in an inverted configuration.

For developing high performance bulk acoustic wave (BAW) filters, a high quality factor (Q) can be generally desirable. Bulk acoustic wave (BAW) devices can include raised and/or suspended frame structures. A raised and/or suspended frame structure can reduce lateral energy leakage from a main acoustically active region of the bulk acoustic wave device. A BAW device can include a single-layer raised frame structure, in some implementations. A BAW device can include a multi-layer raised frame structure, in some implementations. A BAW device can include a raised frame structure having a layer that includes a material with a relatively low acoustic impedance (e.g., lower than one or both of the electrodes and/or the piezoelectric layer), such as silicon dioxide. A BAW device can include a gap (e.g., filled with air) under a raised frame structure such that at least a portion of the raised frame structure is a suspended frame. The suspended frame structure of the BAW device can facilitate achieving a relatively high Q (in some cases, for a region above a resonant frequency and/or an anti-resonant frequency). BAW devices with the raised and/or suspended frame structures disclosed herein can achieve low insertion loss and/or low Gamma loss, in some cases. BAW devices with the raised and/or suspended frame structures disclosed herein can achieve a relatively high electromechanical coupling coefficient (kₜ²), in some cases, which can be desirable for certain applications, such as for relatively wide pass band filters.

To achieve a high Q, a raised frame, which can be referred to as a border ring, can block lateral energy leakage from an active domain of a BAW resonator to a passive domain of the BAW resonator. A raised frame can improve Q, although it may not be able to trap all leakage energy. In some instances, the raised frame can generate a relatively large TE spurious mode, which can be referred to as a raised frame mode, which can be below a main resonant frequency of a BAW resonator. This can cause Gamma degradation in carrier aggregation bands for a filter. Gamma can refer to a reflection coefficient. In some instances, a wider raised frame can be used to provide a higher Q value. However, the wider raised frame can also degrade the electromechanical coupling coefficient (kₜ²), and/or the wider raised frame can produce a larger TE spurious mode and/or lateral spurious mode. A recessed frame which is located between a raised frame and active area can suppress lateral spurious mode with higher resonance frequency than active area in case of type-2 vibration resonator such as AIN based piezoelectric layer. The wider raised frame can also produce increased gamma degradation.

Some aspects of this disclosure relate to a bulk acoustic wave resonator that includes a suspended frame structure that can improve Q, such as below the resonant frequency, as discussed herein. The suspended frame structure can also provide higher kₜ² values, lower amounts of spurious noise, lower insertion loss, and/or lower Gamma loss, as compared to other BAW devices that lack the suspended frame structure. The suspended frame structure can be disposed outside or along a perimeter of an active region of the bulk acoustic wave resonator. In some embodiments, the suspended frame can be disposed outside of a raised frame structure that is not suspended. The raised frame and/or suspended frame can include a material with relatively low acoustic impedance. For instance, the low acoustic impedance material can be disposed between a top electrode and a piezoelectric layer of a bulk acoustic wave resonator. A gap, such as between the piezoelectric layer and the material with low acoustic impedance, can form the suspended frame structure, in some embodiments.

In some implementations, a low Gamma loss can be achieved with a raised frame spurious mode away from carrier aggregation bands. Some embodiments disclosed herein can include a raised frame portion, which can include the low acoustic impedance material, which can produce a spurious mode at a frequency that is lower than for other types of BAW devices. The BAW device can be configured so that the raised frame mode for the spurious mode can be outside of a carrier aggregation band so as not to provide a Gamma loss, or to provide low Gamma loss, in some cases. By way of example, in a carrier aggregation application, a multiplexer can include a common node arranged to receive a carrier aggregation signal, a first filter having a passband associated with a first carrier of the carrier aggregation signal, and a second filter coupled to the first filter at the common node and having a second passband associated with a second carrier of the carrier aggregation signal. The first filter can include a BAW resonator with a raised frame structure with material having a low acoustic impedance as disclosed herein, which can increase Gamma for the first filter in the passband of the second filter. Furthermore, some BAW devices disclosed herein can include a suspended frame portion (e.g., in addition to the raised frame portion), and the suspended frame portion can be configured to suppress the spurious mode. Thus, in some embodiments, the raised frame portion and the suspended frame portion can both contribute to low Gamma loss and to improved performance of the BAW devices.

Also, some raised frame structures disclosed herein can have a low acoustic impedance material configured so that the difference between the effective acoustic impedance of the raised frame domain and the active domain can provide a high Q. In some embodiments, the raised frame structure can provide a high mode reflection of a lateral energy and can decrease mode conversion from main mode to other lateral modes around the anti-resonance frequency. Accordingly, the configuration of a low acoustic impedance layer or material in the raised frame structure can cause Q to be significantly increased, such as relative to other BAW devices or other raised frame structures. In some embodiments, the gap of the suspended frame can at least partially isolate or insulate one or more structures from the piezoelectric layer to reduce the transfer of vibrations therebetween, which increase the Q value and/or other performance parameters of the BAW device, as discussed herein.

Although some embodiments disclosed herein may be discussed with reference to single raised frame structures with a single layer, such as of the low acoustic impedance material, various suitable principles and advantages discussed herein can be applied to a multi-layer raised frame structure that includes two or three or more raised frame layers. For example, in some cases a first raised frame layer can include a relatively low acoustic impedance material, whereas a second raised frame layer can include a relatively high acoustic impedance material. The second raised frame layer can include a material this is heavier or denser than the material of the first raised frame layer. In some cases, the second raised frame layer can be the same material as an electrode of the bulk acoustic wave resonator. The suspended frame can include a gap, such as below the first and second raised frame layers.

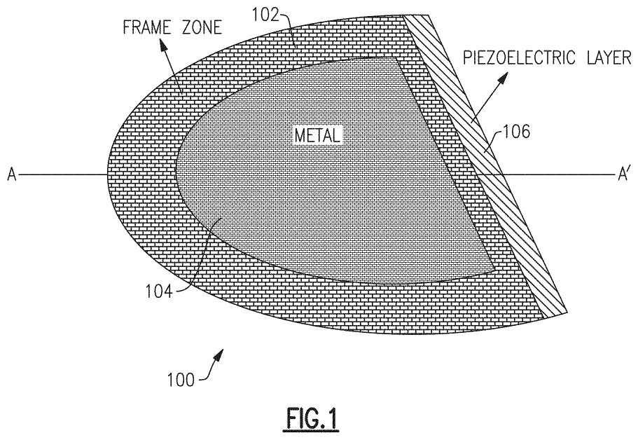

FIG. 1 is a plan view of a raised frame bulk acoustic wave device 100. As shown in FIG. 1, the bulk acoustic wave device 100 can include a frame zone 102 around the perimeter of an active region of the bulk acoustic wave device 100. The frame zone 102 can be referred to as a border ring in certain instances. A suspended frame structure and/or raised frame structure can be in the frame zone 102. The raised and/or suspended frame structures can be implemented in accordance with any suitable principles and advantages disclosed herein. The frame zone 102 can be outside of a middle area 104 of the active region of the bulk acoustic wave device 100. One or more raised frame layers and/or a gap can be in the frame zone 102 and can extend above a metal electrode. FIG. 1 illustrates the metal electrode at the middle area 104 and the raised frame layer at the frame zone 102. One or more other layers can be included over the metal electrode and the raised frame layer. For instance, silicon dioxide can be included over the metal electrode and the raised frame layer. FIG. 1 also illustrates that a piezoelectric layer 106 of the bulk acoustic wave device 100 can be below the metal electrode and the raised frame layer.

Some embodiments of raised frame bulk acoustic wave devices will be discussed with reference to example cross sections along the line from A to A′ in FIG. 1. Any suitable combination of features of the bulk acoustic wave devices disclosed herein can be combined with each other. Any of the bulk acoustic wave devices disclosed herein can be a bulk acoustic wave resonator in a filter, such as arranged to filter a radio frequency signal.

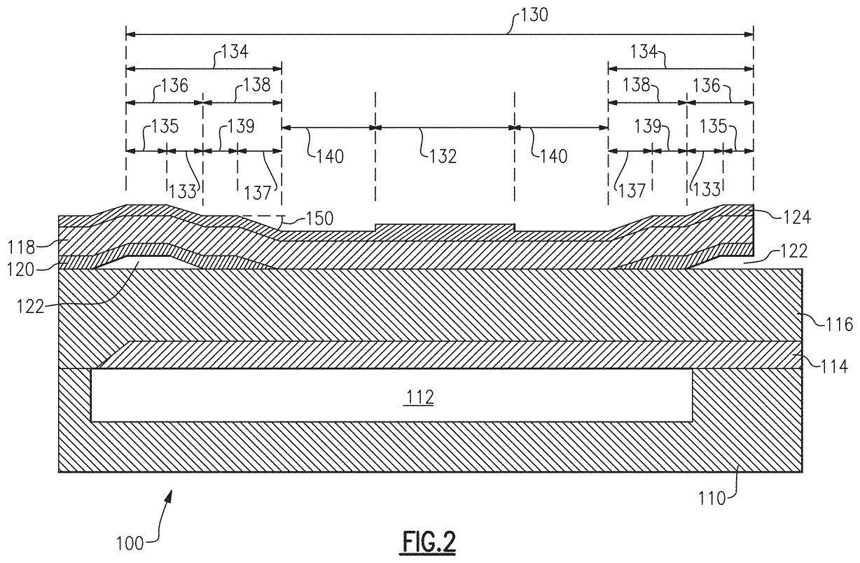

FIG. 2 is a schematic cross-sectional view of an example bulk acoustic wave (BAW) device 100 with a raised frame structure. The BAW device 100 can include a support substrate 110, a cavity 112 (e.g., a reflector cavity), a first or lower electrode 114 positioned over the support substrate 110, a piezoelectric layer 116 positioned over the lower electrode 114, a second or upper electrode 118 positioned over the piezoelectric layer 116, a raised frame structure or layer 120 positioned at least partially between the piezoelectric layer 116 and the upper electrode 118, and a passivation layer 124 positioned over the upper electrode 118.

The support substrate 110 can be a silicon substrate, and other suitable substrates can alternatively be implemented in place of the silicon substrate. One or more layers, such as a passivation layer, can be positioned between the lower electrode 114 and the support substrate 110. In some embodiments, the cavity 112 can be an air cavity.

The piezoelectric layer 116 can be disposed between the first electrode 114 and the second electrode 118. The piezoelectric layer 116 can be an aluminum nitride (AlN) layer or any other suitable piezoelectric layer. An active region 130 or active domain of the BAW device 100 can be defined by the portion of the piezoelectric layer 116 that overlaps with both the lower electrode 114 and the upper electrode 118, for example over an acoustic reflector, such as the cavity 112. The lower electrode 114 and/or the upper electrode 118 can have a relatively high acoustic impedance. For example, the lower electrode 114 and/or the upper electrode 118 can include molybdenum (Mo), tungsten (W), ruthenium (Ru), iridium (Ir), platinum (Pt), an alloy that include Ir and Pt, or any suitable alloy and/or combination of any of these materials, although other suitable conductive materials could be used. The upper electrode 118 can be formed of the same material as the lower electrode 114 in certain instances, although different materials can be used for the lower electrode 114 and the upper electrode 118, in some cases.

The illustrated BAW device 100 can include an active region 130 that has a main acoustically active region 132 and a raised frame region 134 at least partially, or fully, surrounding the main acoustically active region 132 (e.g., in plan view). In the cross-sectional view of FIG. 2, the raised frame region 134 can be on opposing sides of the main acoustically active region 132. The main acoustically active region 132 may be referred to as a center region or middle area of the active region 130. The main acoustically active region 132 can set the main resonant frequency of the BAW device 100. There can be a significant (e.g., exponential) fall off of acoustic energy in the piezoelectric layer 116 for a main mode in the raised frame region 134 relative to the main acoustically active region 132. A recessed frame region 140 can be positioned between the main acoustically active region 132 and the raised frame region 134.

The raised frame layer 120 can be positioned between the first or lower electrode 114 and the second or upper electrode 118. As illustrated in FIG. 2, the raised frame layer 120 can be positioned between the piezoelectric layer 116 and the second electrode 118. The raised frame layer 120 can extend beyond the active region 130 of the bulk acoustic wave device 100 as shown in FIG. 2, which can be beneficial for manufacturability reasons in certain instances.

The raised frame layer 120 can be a low acoustic impedance material. The low acoustic impedance material can have a lower acoustic impedance than the material of the first electrode 114. The low acoustic impedance material has a lower acoustic impedance than the material of the second electrode 118. The low acoustic impedance material can have a lower acoustic impedance than the material of the piezoelectric layer 116. As an example, the raised frame layer 120 can be a silicon dioxide (SiO2) layer. Other oxide materials can be used, and the raised frame structure or layer 120 can be an oxide raised frame structure or layer. The raised frame layer 120 can be a silicon nitride (SiN) layer, a silicon carbide (SiC) layer, or any other suitable low acoustic impedance layer. The raised frame layer 120 can have a relatively low density. The density and/or acoustic impedance of the raised frame layer 120 can be lower than the density and/or acoustic impedance of the lower electrode 114, of the upper electrode 118, and/or of the piezoelectric layer 116 of the BAW device 100.

The BAW device 100 can have a gap 122 (e.g., a cavity or recess) under at least a portion of the raised frame structure. The gap 122 can be formed between the raised frame layer 120 and the piezoelectric layer 116. The gap 122 can be filled with air, in some embodiments, although it can contain any suitable material. The gap 122 can be an air gap or cavity. The gap 122 can be a void. The gap 122 can be formed using a sacrificial layer, such as using polysilicon, or any other suitable material that can be removed during the manufacturing process to create the gap 122. The gap 122 can suspend the above-lying layers. The gap can elevate one or more layers to at least partially define the raised frame structure 134.

The raised frame structure 134 can have a suspended frame portion 136 and an inner raised frame portion 138. The suspended frame portion 136 can be positioned above the gap 122. The gap 122 can suspend one or more of the raised frame layer 120, the upper electrode 118, and/or the passivation layer 124. The inner raised frame portion 138 is not positioned over the gap 122, in some configurations. The inner raised frame portion 138 can be disposed inward of the suspended frame portion 136 (e.g., closer to the main acoustically active region 132) and/or inward of the gap 122. The suspended frame portion 136 can be taller than the inner raised frame portion 138. For example, the suspended frame portion 136 can extend further in a direction that is normal to the piezoelectric layer 116 than the inner raised frame portion 138. The inner raised frame portion 138 can be elevated by the thickness of the raised frame layer 120. The suspended frame portion 136 can be elevated by the thickness of the gap 122 as well as the thickness of the raised frame layer 120. The gap 122 can increase the height of the BAW device 100 in the raised frame region 134. Accordingly, the BAW device 100 can have a greater height in the suspended frame region 136 than in other portions of the active region 130, such as the middle area of the active domain.

The inner raised frame portion 138 can have a gradient region 137 and a non-gradient region 139. The non-gradient portion 139 of the inner raised frame portion 138 can be substantially parallel to the piezoelectric layer 116 (e.g., to the upper surface thereof). The raised frame layer 120 at non-gradient portion 139 can have a substantially uniform thickness. The raised frame layer 120 at the gradient portion 137 can be angled downward and/or tapered. The upper surface of the gradient portion 137 of the inner raised frame portion 138 (or of the raised frame layer 120) can form an angle 150 relative to upper surface of the non-gradient portion 139 of the inner raised frame portion 138 (or of the raised frame layer 120). The first raised frame layer 120 can have a decreasing thickness moving along a direction from the raised frame structure toward the main acoustically active region 132 (or middle area).

The suspended frame portion 136 can have a gradient region 133 and a non-gradient region 135. The non-gradient portion 135 of the suspended frame portion 136 can be substantially parallel to the piezoelectric layer 116 (e.g., to the upper surface thereof). The raised frame layer 120 at the non-gradient portion 135 can have a substantially uniform thickness. The raised frame layer 120 at the gradient portion 137 of the suspended frame 136 can have a substantially uniform thickness. The taper of the gap 122 can provide the gradient for the gradient portion 133. The thickness of the gap 122 can be tapered or narrowing along an inward direction. The upper surface of the gradient portion 133 of the suspended frame portion 136 (or the underside of the raised frame layer 120) can form an angle 150 relative to upper surface of the non-gradient portion 135 of the suspended frame portion 136 (or of the raised frame layer 120). The suspended frame portion 136 can have a decreasing thickness or height moving along a direction from the raised frame structure toward the main acoustically active region 132 (or middle area).

In some embodiments, the gap 122 can be open on a first side (e.g., the right side of FIG. 2), the gap 122 can be closed on a second side (e.g., the left side of FIG. 2). The gap 122 can have an inner tapered side with a tapered thickness (e.g., which can correspond to the gradient portion 133), and the gap 122 can have an outer tapered side with a tapered thickness (e.g., which can be outside the active region 130). The raised frame layer 120 can abut against the piezoelectric layer 116 at an inner area (e.g., associated with the inner raised frame portion 138). Moving radially outwardly, the raised frame layer 120 can angle away from the piezoelectric layer 116 (e.g., at the gradient portion 133), and can extend generally parallel to the piezoelectric layer 116 (e.g., at the non-gradient portion 135). The raised frame layer 120 can angle back towards, and then abut against, the piezoelectric layer 116 (e.g., at a region radially outside of the active region 130). Thus, the gap 122 can be enclosed, such as between the raised frame layer 120 and the piezoelectric layer 116. Many variations are possible. For example, the gap 122 can be closed on both sides (e.g., similar to the left side of FIG. 2). Alternatively, the gap 122 could be open on both sides (e.g., similar to the right side of FIG. 2).

The gap 122 can extend circumferentially around the BAW device 100, such as along the periphery of the active region 130, or along the periphery of the raised frame region. The gap 122 can be a single, continuous cavity that extends around the BAW device 100 (e.g., by a full 360 degrees), or the gap 122 can have a plurality of sub-portions or cavities that can be isolated from each other, such as by walls or structural supports, etc. In some cases, a cross-section taken through the BAW device 100 (e.g., along the line from A to A′ in FIG. 1) can have a first gap portion (e.g., the gap 122 portion on the left of FIG. 2) and a second gap portion (e.g., the gap 122 portion on the right of FIG. 2). The main acoustically active region 132 can be between the first and second gap portions. The first and second gap portions can have substantially symmetrical cross-sectional areas and/or shapes, at least for the parts of the first and second gap portions within the active region 130. In some cases, a portion of the first gap portion or the second gap portion that is outside the active region 130 (e.g., outward of the lower electrode 114, outward of the piezoelectric layer 116, and/or outward of the upper electrode 118) can be asymmetrical relative to a corresponding portion of the other of the second gap portion or the first gap portion. By way of example, with reference to FIG. 2, the inward tapered portions of the first and second gap portions (e.g., corresponding to the gradient portions 133) can be substantially symmetrical. Some or all of the non-gradient portions, or uniform-thickness portions, (e.g., corresponding to the non-gradient region 135) can be substantially symmetrical between the first and second gap portions. In the example of FIG. 2, the left gap portion can have an outer tapered portion, whereas the right gap portion does not. For example, the outward side of the right gap portion can be open. The symmetry of the gap portions can be beneficial to the performance of the BAW device.

Many variations are possible. In some embodiments, both of the gap portions can be closed. For example, the gap portion on the right side of FIG. 2 can be closed, and can be similar to or symmetrical with the gap portion on the left side of FIG. 2. In some embodiments, the gap portions can be open. For example, the gap portion on the left side of FIG. 2 can be open, and can be similar to or symmetrical with the gap portion on the right side of FIG. 2.

The passivation layer 124 can be positioned over the upper electrode 118, and/or over the raised frame layer 120, and/or over the gap 122. The passivation layer 124 can be a silicon dioxide layer, although any suitable passivation material can be used. The passivation layer 124 can be formed with different thicknesses in different regions of the BAW device 100. For example, as shown in FIG. 2, the passivation layer 124 can be thinner in the recessed frame region 140 than in the main acoustically active region 132, or than in other portions such as the raised frame region 134. In some cases, the recessed frame region 140 can contribute to achieving the relatively high Q, such as below the resonant frequency. By way of example, the combination of the recessed frame region 140 and the raised frame structure of the BAW device 100 can contribute to achieving the relatively high Q, such as below the resonant frequency. In some embodiments, the recessed frame region 140 can be omitted, such as by using a passivation layer 124 that has a substantially uniform thickness. Also, in some embodiments, the passivation layer 124 can be omitted.

A gradient portion of the raised frame structure can have an angle 150 with respect to a horizontal direction. The angle 150 can be with respect to an underlying layer (e.g., a piezoelectric layer). The gradient portion of the raised frame layer 120 or overlying layer(s) can have an upper surface that is angled (e.g., downward or towards the piezoelectric layer 116 or lower electrode 114) by an angle 150. The gradient angle 150 of the raised frame layer 120 can affect the layers above the raised frame layer 120. The gap 122 can also have a gradient portion that has the gradient angle 150, which can similarly affect the overlying layer(s). The gradient portion 133 of the suspended frame portion 136 can have the gradient angle 150. The gradient portion 137 of the inner raised frame portion 138 can have the gradient angle 150, which can be the same as or different from the gradient angle of the suspended frame 136. The upper electrode 118 and/or the passivation layer 124 can also have the gradient angle 150. The gradient angle 150 can be less than 90° or less than about 40°, in some embodiments. In some cases, the taper angle can be about 5°, about 10°, about 15°, about 20°, about 30°, about 45°, about 60°, about 75°, or any values therebetween, or any ranges between any of these values. For example, in some instances, the angle 150 can be in a range from about 10° to about 30° for a gradient portion of a raised frame portion and/or suspended frame portion in a gradient region, or for other associated layers. In some embodiments, the gradient angle 150 can vary along the length of the associated gradient portion. For example, a gradient portion can start with a smaller angle and can transition to a larger angle. In some cases, the gradient portion can have curvature.

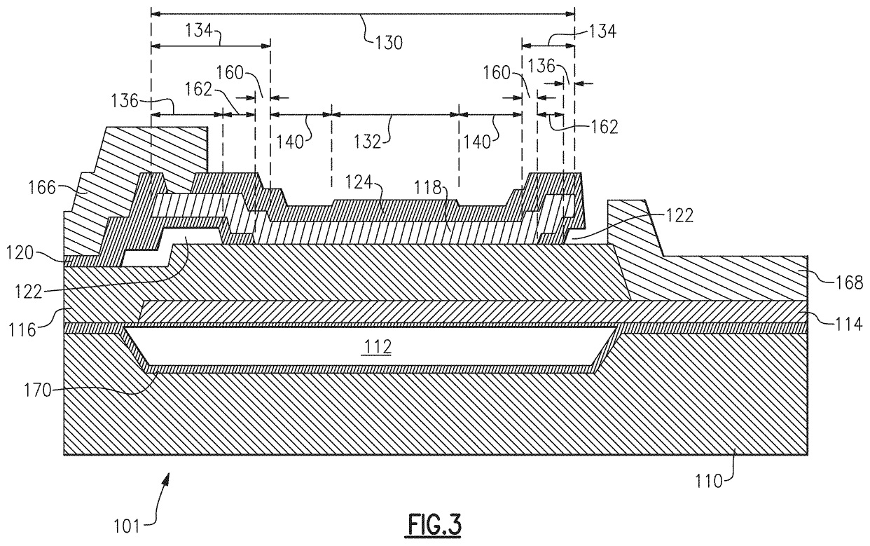

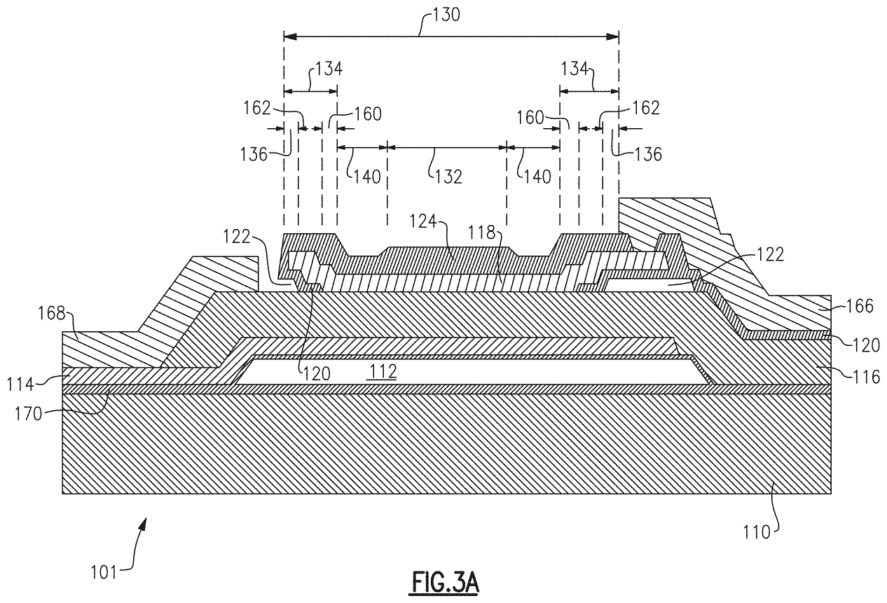

FIG. 3 shows a cross-sectional view of a BAW device 101, which can be similar to the BAW device 100 of FIG. 2, except as discussed herein. FIG. 3A shows a cross-sectional view of a BAW device 101, which can be similar to the BAW device 100 of FIG. 2 or the BAW device 101 of FIG. 3, except as discussed herein. FIG. 3B shows a cross-sectional view of a BAW device 101, which can be similar to the BAW device 100 of FIG. 2 or the BAW device 101 of FIGS. 3 and/or 3A, except as discussed herein. The BAW device 101 can include a support substrate 110, a cavity 112 (e.g., a reflector cavity), a first or lower electrode 114 positioned over the support substrate 110, a piezoelectric layer 116 positioned over the lower electrode 114, a second or upper electrode 118 positioned over the piezoelectric layer 116, a raised frame structure or layer 120 positioned at least partially between the piezoelectric layer 116 and the upper electrode 118, a gap 122 (e.g., a cavity) between the piezoelectric layer 116 and the raised frame layer 120, and a passivation layer 124 positioned over the upper electrode 118.

The BAW device 101 can have an active region 130 or active domain, which can be defined by the portion of the piezoelectric layer 116 that overlaps with both the lower electrode 114 and the upper electrode 118. A main acoustically active region 132 may be at a center region or middle area of the active region 130. A recessed frame region 140 can be disposed outward of the main acoustically active region 132. A raised frame region 134 or structure can be disposed outward of the recessed frame region 140.

The raised frame region 134 can include a first raised frame portion 160, a second raised frame portion 162, which can be disposed outward of the first raised frame portion 160, and a suspended frame portion 136, which can be disposed outward of the second raised frame portion 162. The first raised frame portion 160 can have a first height, and the second raised frame portion 162 can have a second height that is larger than the first height. The raised frame layer 120 can abut against the piezoelectric layer 116 along a first area, and the raised frame layer 120 can step up to form a gap 122 between the raised frame layer 120 and the piezoelectric layer 116 along a second area. The second area can be disposed outward of the first area. In some embodiments, the height of the first raised frame portion 160 can be substantially the same as a thickness of the raised frame layer 120 (e.g., at least at the first area that abuts against the piezoelectric layer 116). The first raised frame portion 160 can be produced by at least the upper electrode 118 stepping up and being elevated by the raised frame layer 120 (e.g., the first area of the raised frame layer 120).

In some embodiments, the height of the second raised frame portion 162 can be substantially the same as the combined thickness of the gap 122 and the raised frame layer 120 (e.g., at least at the second area above the gap 122). The difference in height of the second raised frame portion 162 and the first raised frame portion 160 can be substantially the same as the thickness of the gap 122. The second raised frame portion 162 can be produced by at least the upper electrode 118 stepping up and being elevated by the raised frame layer 120 (e.g., the second area thereof) and the gap 122.

The suspended frame portion 136 can have the same height as the second raised frame portion 162, in some embodiments. The suspended frame portion 136 can be the portion of the raised frame structure that is directly above the gap 122. The second raised frame portion 162 can be the portion of the raised frame structure that is elevated above the first raised frame portion 160 (e.g., by the gap 122), but is not directly above the gap 122, such as due to the thickness of the material at the gradient portions or angled steps of the layer(s). In some embodiments, the suspended frame portion 136 can be considered a portion of the second raised frame portion 162 that is positioned above the gap 122. In some configurations, the full second raised frame portion 162 can be disposed above the gap 122, so that the second raised frame portion 162 is also the suspended frame portion 136 (e.g., similar to the configuration of FIG. 2).

In some embodiments, the raised frame region 134 can include a suspended frame portion 136 that corresponds to the portion of the raised frame structure that is directly above the gap 122, or that is suspended over the gap 122. The suspended frame portion can correspond to the second area of the raised frame layer 120, which is spaced apart from the piezoelectric layer 116 by the gap 122. The second raised frame portion 162 can correspond to the first area of the raised frame layer 120, which can abut against the piezoelectric layer 116, or is otherwise not be above the gap 122. The first raised frame portion 160 can correspond to an area of the upper electrode 118 that is elevated by the raised frame layer 120. In some embodiments, a portion of the elevated upper electrode 118 can be disposed inward from the raised frame layer 120, such as because of the thickness of the material at the gradient portion or angled step.

In some embodiments, the piezoelectric layer 116 can have a step (e.g., which can be defined by the piezoelectric layer 116 stepping up to be disposed over the lower electrode 114. The gap 122 can include a step that corresponds to the step in the piezoelectric layer 116. At least part of an upper portion of the gap 122 be disposed above the lower electrode 114, and at least part of the lower portion of the gap 122 is not disposed over the lower electrode 114. The lower portion of the gap can extend outward past and end of the lower electrode 114. The step can be between the upper and lower portions of the gap 122, as shown on the left of FIG. 3. In some embodiments, the step in the gap 122 can be omitted (e.g., as shown in FIG. 2). In some embodiments, the suspended frame 136 can be larger on one side (e.g., the left side in FIG. 3) than the other side (e.g., the right side in FIG. 3). In some embodiments, the upper electrode 118 can extend over the step in the gap 122. In some embodiments, the active area 130 can extend over the step in the gap 122. In some configurations, the gap portions (e.g., at least the portions of the gap portions that overlap the active area 130) can be asymmetrical (e.g., as shown in FIG. 3), or they can be substantially symmetrical, as discussed herein.

In some embodiments, a portion of the gap 122 can be open (e.g., as shown in the right of FIG. 3). The passivation layer 124 can extend across one or both ends of the upper electrode 118 and can meet with the raised frame layer 120 that is disposed below the upper electrode 118. In some embodiments, the raised frame layer 120 and the passivation layer 124 can be made of the same material (e.g., silicon dioxide or other oxide material). The raised frame layer 120 and/or the passivation layer 124 can extend down to the piezoelectric layer 116 (or other underlying layer) at a location that is outward of the gap 122, which can close at least a portion of the gap 122 (e.g., as shown on the left of FIG. 3).

In some embodiments, a first conductive layer 166 can be disposed over at least a portion of the passivation layer 124. The passivation layer 124 can have an opening, which can permit electrical connection between the first conductive layer 166 and the upper electrode 118. The first conductive layer 166 can extend into or through the opening to contact the upper electrode 118. The opening or electrical contact between the first conductive layer 166 and the upper electrode 118 can be disposed directly over the gap 122, although other locations could also be used. The conductive layer 166 can contact the upper electrode 118, can extend through the opening in the passivation layer 124, and/or can extend outward from the opening (e.g., above the passivation layer 124). Electrical signals and/or electrical power can be delivered to and/or from the upper electrode 118 through the first conductive layer. The opening or electrical contact between the first conductive layer 166 and the upper electrode 118 can be disposed directly above the lower electrode 114, the piezoelectric layer 116, the upper electrode 118, a portion of the gap 122, and/or a portion of the raised frame layer 120. In some embodiments, the active region 130 can omit the area covered by the first conductive layer 166, as shown in FIGS. 3A and 3B, even if that area includes overlapping of the piezoelectric layer 116, the lower electrode 114, and the upper electrode 118.

In some embodiments, a second conductive layer 168 can be disposed over a portion of the lower electrode 114. For example, a portion of the lower electrode 114 can extend outward past an end of the piezoelectric layer 116 (e.g., on the right side of FIG. 3). The second conductive layer 168 can be positioned over (e.g., in direct contact with) that portion of the lower electrode 114. The second conductive layer 168 can be provide electrical signals and/or electrical power to and/or from the lower electrode 168. In some embodiments, either or both of the first conductive layer 166 and the second conductive layer 168 can be omitted. For example, electrical signals can be delivered directly to or from either or both of the electrodes 114, 118, in some implementations.

The first conductive layer 166 and/or the second conductive layer 168 can be made of a material that has higher electrical conductivity than the upper electrode 118 or the lower electrode 114. For example, the first conductive layer 166 and/or the second conductive layer 168 can be made from gold or another conductive metal (e.g., copper or aluminum). In some embodiments, a material for the upper electrode 118 and/or the lower electrode 114 can have a relatively high acoustic impedance even if the electrical conductivity is not optimal. In some embodiments, the upper electrode 118 and/or the lower electrode 114 can include a material with higher acoustic impedance and/or lower electrical conductivity than the material of the first conductive layer 166 and/or the second conductive layer 168. The first conductive layer 166 and/or the second conductive layer 168 can have less effect on the acoustic vibrations, as compared to a BAW device that uses the relatively high acoustic impedance material of the electrode(s) 114, 118 to deliver electrical signals. The conductive layer 166 can be disposed above the gap 122, and the gap 122 can insulate the conductive layer 166 from vibrations. Also, the first conductive layer 166 and/or the second conductive layer 168 can reduce ohmic loss, as compared to a BAW device that uses the lower conductivity material of the electrode(s) 114, 118 to deliver electrical signals. The BAW device 100 of FIG. 2, and other embodiments disclosed herein, can include the first conductive layer 166 and/or the second conductive layer 168, similar to the BAW device 101 of FIG. 3.

As shown in FIGS. 2, 3, and 3B, the cavity 112 can be a recess formed in the substrate 110. The lower electrode 114 can extend along a plane from the connection with the second conductive layer 168. As shown in FIG. 3A, in some embodiments, the cavity 112 can be formed above the substrate 110. The top surface of the substrate 110 can be planar. The lower electrode 114 and/or the piezoelectric layer 116 can include a step, with a lower region (e.g., which can be next to the cavity 112) and an upper region (e.g., which can be above the cavity 112). In some embodiments, the gap 122 can have a step (e.g., as shown in FIG. 3), with a lower portion (e.g., which can be next to a portion of the piezoelectric layer 116) and an upper portion (e.g., which can be above the portion of the piezoelectric layer 116). As shown in FIGS. 2, 3A, and 3B, in some embodiments, the gap 122 can be disposed on a single plane, such as without the step shown in FIG. 3.

In some embodiments, the BAW device 101 can include an oxide layer 170 (e.g., silicon dioxide) between the substrate 110 and the lower electrode 114. The oxide layer 170 can partially or completely surround the cavity 112. The other BAW devices disclosed herein can include the oxide layer 170. In some embodiments, the oxide layer 170 can be omitted.

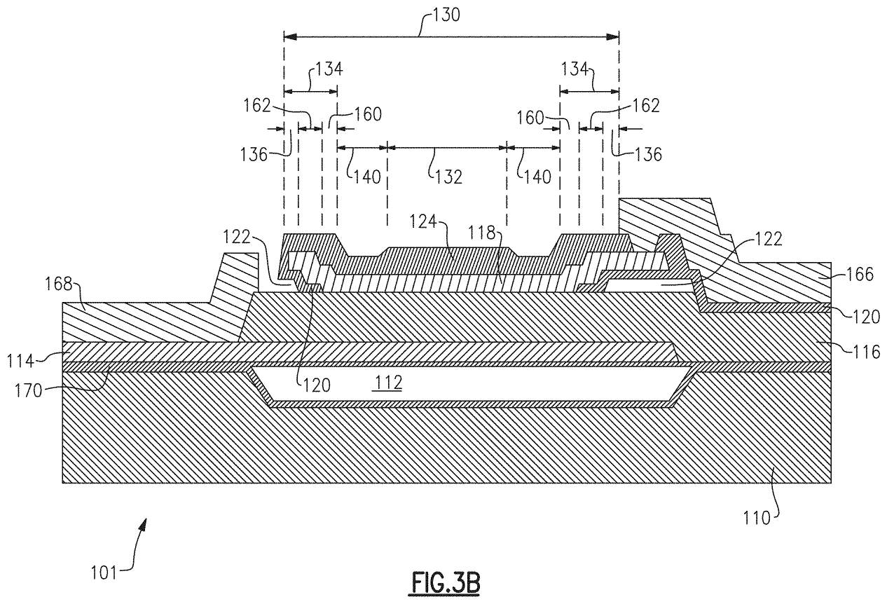

The BAW device designs disclosed herein can have improved performance, such as by improving the Q value, improving the kt² value, and/or reducing the spurious mode. FIG. 4 shows an example of a BAW device 103, which can be similar to the BAW devices 100 and/or 101 of FIG. 2 and/or 3, except that the BAW device 103 does not include the gap 122 or the suspended frame 136. The BAW device 103 can include a raised frame 134 structure that can be raised by the raised frame layer 120. FIG. 4A shows an example of a BAW device 103, which can be similar to the BAW device 101 of FIG. 3A, except that the BAW device 103 does not include the gap 122 or suspended frame 136.

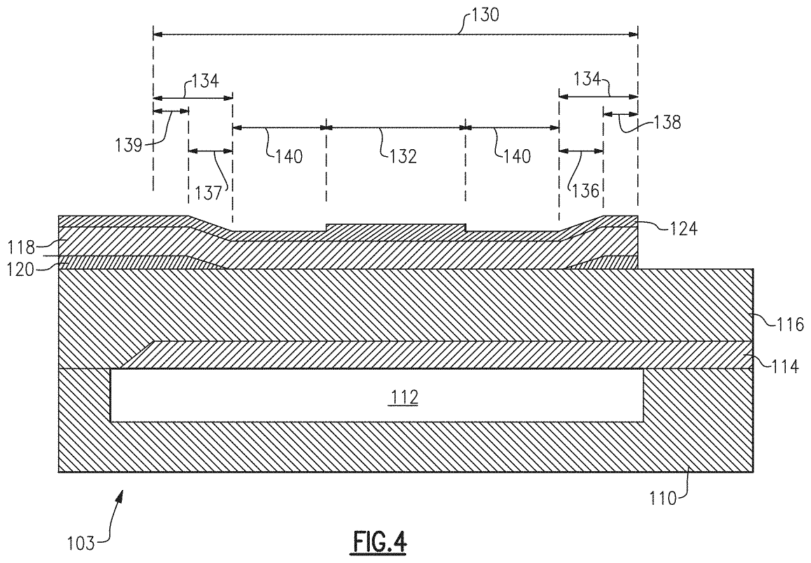

FIG. 5 shows a graph that compares Q values for a BAW device 103 similar to FIGS. 4 and 4A, which is represented by line 502, to Q values for a BAW device 101 similar to FIGS. 3 to 3B, which is represented by line 504. As can be seen in FIG. 5, the BAW device 101 that has the gap 122 and suspended frame 136 can have a higher Q values and a higher maximum Q value than the BAW device 103 that lacks the gap 122 and suspended frame 136. For example, in FIG. 5, the BAW device 101 can have a maximum Q value that is about 45% higher than the maximum Q value of the BAW device 103.

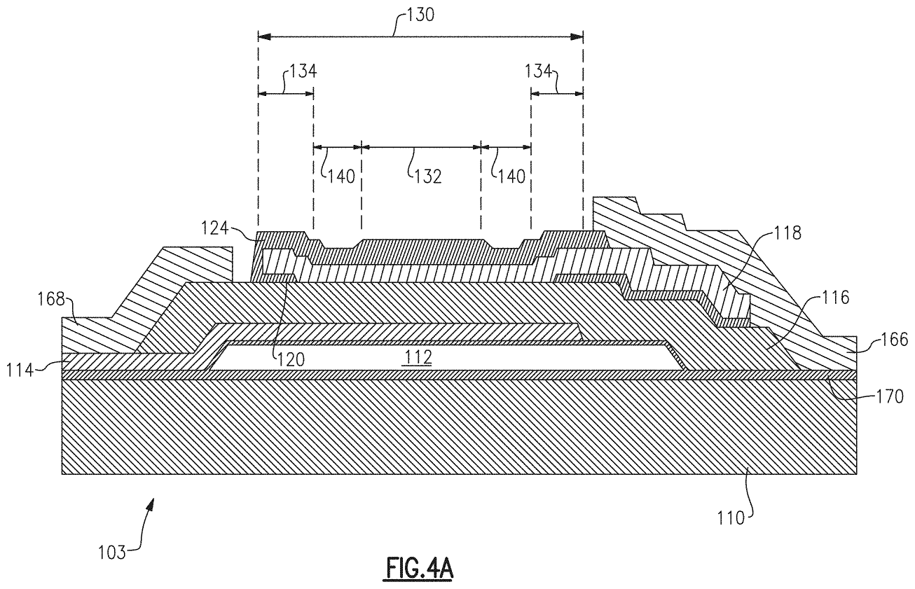

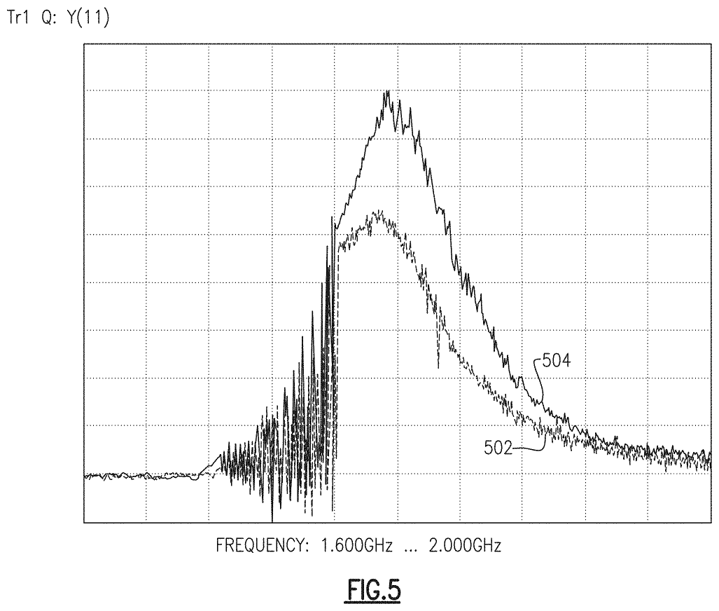

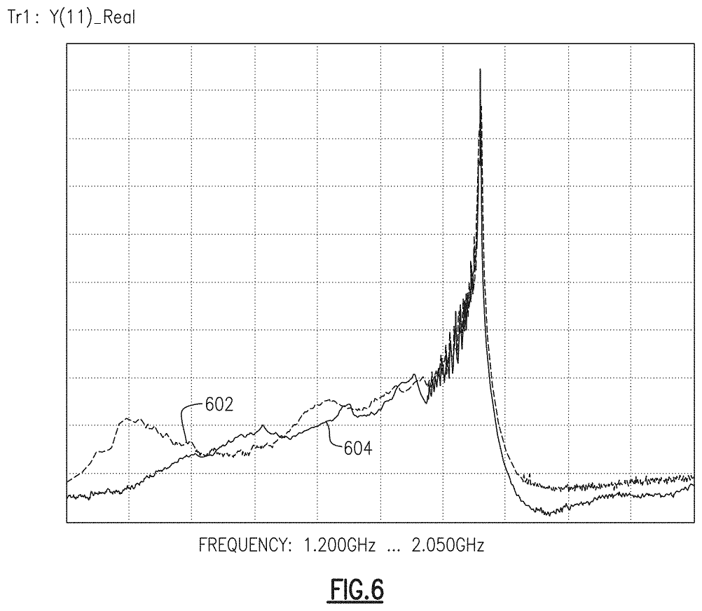

FIG. 6 shows a graph that compares the conductance (dB) of a BAW device 103 similar to FIGS. 4 and 4A, which is represented by line 602, to the conductance of a BAW device 101 similar to FIGS. 3 to 3B, which is represented by line 604. As can be seen in FIG. 6, the BAW device 101 that has the gap 122 and suspended frame 136 can have lower spurious noise than the BAW device 103 that lacks the gap 122 and suspended frame 136 (e.g., for most of the frequency range below the resonant frequency). For example, in FIG. 6, at about 1.285 GHz, the BAW device 103 can have higher conductance than the BAW device 101. At about 1.285 GHz, the BAW device 101 can have about 22% lower conductance (in dB) (e.g., of spurious noise) than the BAW device 103. Also, at about 1.54 GHz, the BAW device 103 can have higher conductance than the BAW device 101. Conductance of the BAW device 101 can be lower than the conductance of BAW device 103 for frequencies above the resonant frequency, as shown in FIG. 6.

FIG. 7 shows a graph that compares the admittance of a BAW device 103 similar to FIGS. 4 and 4A, which is represented by line 702, to the admittance of a BAW device 101 similar to FIGS. 3 to 3B, which is represented by line 704. The electromechanical coupling coefficient (kₜ²) can be associated with the difference between the series resonant frequency (fₛ) and the parallel resonant frequency (Fₚ). As can be seen in FIG. 7, the BAW devices 101, 103 can both have Fₛ values at about 1.76 GHz. The BAW device 101 that has the gap 122 and suspended frame 136 can have an Fₚ value of about 1.83 GHz, whereas the BAW device 103 that does not have the gap 122 and suspended frame 136 can have an Fₚ value of about 1.825 GHz. Thus, the BAW device 101 that has the gap 122 and suspended frame 136 can have a higher kₜ² value than the BAW device 103 that does not have the gap 122 and suspended frame 136.

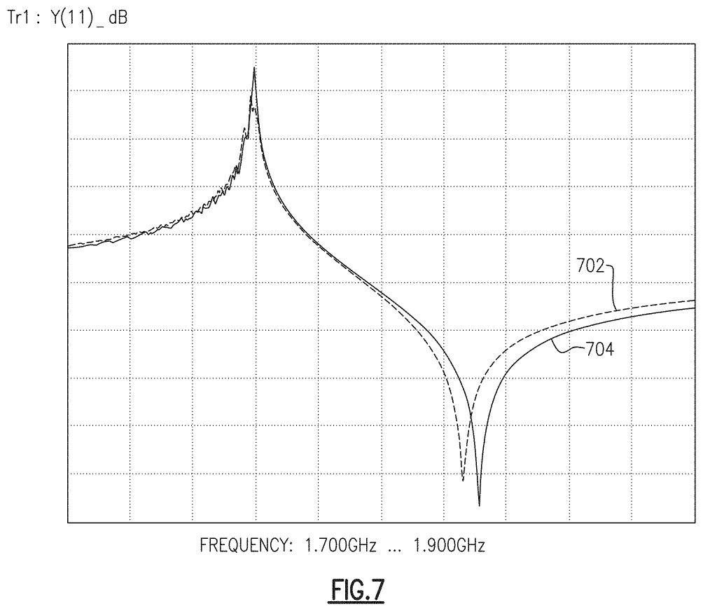

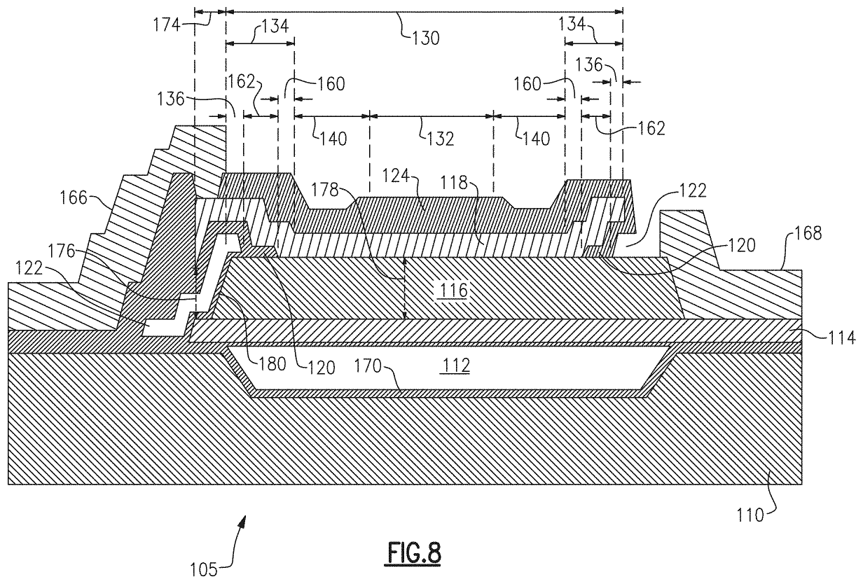

FIG. 8 shows a cross-sectional view of a BAW device 105, which can be similar to the BAW device 101 of FIG. 3, except as discussed herein. The BAW device 105 can include a support substrate 110, a cavity 112, a first or lower electrode 114 positioned over the support substrate 110, a piezoelectric layer 116 positioned over the lower electrode 114, a second or upper electrode 118 positioned over the piezoelectric layer 116, a raised frame structure or layer 120 positioned at least partially between the piezoelectric layer 116 and the upper electrode 118, a gap 122 between the piezoelectric layer 116 and the raised frame layer 120, and a passivation layer 124 positioned over the upper electrode 118.

The BAW device 105 can have an active region 130 or active domain, which can be defined by the portion of the piezoelectric layer 116 that overlaps with both the lower electrode 114 and the upper electrode 118. A main acoustically active region 132 may be at a center region or middle area of the active region 130. A recessed frame region 140 can be disposed outward of the main acoustically active region 132. A raised frame region 134 or structure can be disposed outward of the recessed frame region 140. The BAW device 105 can include a suspended frame structure or portion 136, which can be suspended above the gap 122.

The piezoelectric layer 116 of the BAW device 105 can have a smaller lateral width than in some other BAW designs. Comparing FIG. 8 to FIG. 3, it can be seen that the piezoelectric layer 116 of the BAW device 101 (FIG. 3) can extend outwardly past both the upper electrode 118 and the lower electrode 114 (e.g., on the left side of FIG. 3), whereas both the upper electrode 118 and the lower electrode 114 can extend outwardly past the piezoelectric layer 116 in the BAW device 105 (e.g., on the left side of FIG. 8). The gap 122 can be disposed between the portions of the upper electrode 118 and the lower electrode 114 that extend laterally beyond the piezoelectric layer 116. In some configurations, the gap 122 can isolate a portion of the upper electrode 118 from a portion of the lower electrode 114, so that the piezoelectric layer 116 does not need to extend between those portions of the upper electrode 118 and lower electrode 114. A portion of the upper electrode 118 can overlap a portion of the lower electrode 114 without the piezoelectric layer therebetween at an area or region 174. The gap 122 can extend across some or all of the region 174. The gap 122 can extend outwardly past the piezoelectric layer 116, past the lower electrode 114, and/or past the upper electrode 118.

The upper electrode 118 can extend outwardly past the piezoelectric layer 116. In some embodiments, a portion of the upper electrode 118 can extend downward to cover at least a portion of a lateral end of the piezoelectric layer 116. The upper electrode 118 can have a first portion that extends laterally (e.g., a middle or main acoustically active region 132 of the BAW device 105), a second portion that extends longitudinally in a first direction away from the piezoelectric layer 116 (e.g., upward in FIG. 8, or away from the lower electrode 114), such as to form part of the raised frame 134 and/or suspended frame 136, and a third portion that extends longitudinally in a second direction opposite the first direction (e.g., downward in FIG. 8, or towards the lower electrode 114). The second portion can be laterally outward of the first portion, and the third portion can be laterally outward of the second portion. The third portion of the upper electrode 118 can wrap around a lateral end of the piezoelectric layer 116. The third portion of the upper electrode 118 can extend further in the second direction than the second portion extends in the first direction. In some embodiments, the lower electrode 114 can extend laterally further than the upper electrode 118.

A portion of the upper electrode 118 can be spaced away from a portion of the lower electrode 114 by a distance 176 that is less than the thickness 178 of the piezoelectric layer 116. In some embodiments, an insulating material 180 can cover at least a portion of the lateral end of the piezoelectric layer 116, such as on a side where the upper electrode 118 and/or lower electrode 114 extend outwardly past the piezoelectric layer 116. The insulating material 180 can be silicon dioxide, or another suitable oxide material. In some embodiments, the insulating material 180 can be a portion of, or interconnected by the same material with, the oxide layer 170, the raised frame layer 120, and/or the passivation layer 124. The insulating material 170 can be disposed between the lower electrode 114 and the gap 122. The insulating material 170 can be disposed between the upper electrode 118 and the gap 122. In some embodiments, the insulating material 170 can cover a cross-sectional area of the gap 122 on one side of the BAW device 105, except for an exposed area of the piezoelectric layer 116 at the suspended frame region 136. A line extending (e.g., longitudinally or perpendicular to a plane defined by the piezoelectric layer 116, such as vertically in FIG. 8 and out-of-the-page in FIG. 1) between the upper electrode 118 and the lower electrode 114 can intersect the gap 122 without intersecting the piezoelectric layer 116. The line can extend from the upper electrode 118, through insulating material 180, through the gap 122, through insulating material 180, to the lower electrode 114. The gap 122 can extend laterally past an end of the upper electrode 118, past an end of the lower electrode 114, and/or past an end of the piezoelectric layer 116 (e.g., at the left side of FIG. 8). A portion of the gap 122 can extend downward past a lower surface of the upper electrode 118. A portion of the gap 122 can extend downward past a lower surface of the piezoelectric layer 116. Portions of the gap 122 can be positioned laterally to the side of the upper electrode 118, the piezoelectric layer 116, and the lower electrode 114. The height of the gap can be taller than the thickness of the piezoelectric layer 116. In some embodiments, a first portion of the gap 122 extends over a portion of the top of the piezoelectric layer 116, and a second portion of the gap 122 extends along a lateral end of the piezoelectric layer 116, and/or a third portion of the gap 122 extends lower than a bottom of the piezoelectric layer 116.

In some embodiments, the piezoelectric layer 116 can have no steps, no raised or lowered portions, and/or no recesses. The piezoelectric layer can have no portion that extends past or through a plane defined by the upper surface of the piezoelectric layer 116 at the main acoustically active region 132. The piezoelectric layer 116 can have no portion that extends past or through a plane defined by the lower surface of the piezoelectric layer 116 at the main acoustically active region 132.

The BAW device 105 of FIG. 8 can be more symmetrical than some other BAW designs, which can improve performance of the BAW device 105. In some embodiments, a cross-section of the piezoelectric layer 116 (e.g., as shown in FIG. 8) can be symmetrical, such as across a longitudinal line (e.g., vertical in FIG. 8). In some embodiments, an end of the active region 130 can be defined by a lateral end of the piezoelectric layer 116. The active region 130 of FIG. 8 can be more symmetrical than the active region of FIG. 3, for example. Because the end of the piezoelectric layer 116 cuts off the active area 130 in FIG. 8, the suspended frame portion 136 of the active region 130 can have similar widths on both sides of the BAW device 105, even though one side (e.g., the left side of FIG. 8) of the upper electrode 118 and/or the gap 122 can extend laterally outward further than on the other side (e.g., the right side in FIG. 8) of the BAW device 105. For a cross-section taken though a middle or main acoustically active region 132 of the BAW device 105, a gap 122 portion (or suspended frame region 136) on one side (e.g., the left side of FIG. 8) can have a lateral width that is about 1.25 times, about 1.5 times, about 1.75 times, about 2 times, about 2.5 times, about 3 times, about 3.5 times, about 4 times, about 4.5 times, about 5 times, about 6 times, about 7 times, about 8 times, about 9 times, about 10 times the lateral width of the gap 122 portion (or suspended frame region 136) on the other side (e.g., the right side of FIG. 8), or any values or ranges therebetween, although other configurations are possible. In some embodiments, the lateral width of a portion of the suspended frame 136 in the active region 130 on one side (e.g., the left side of FIG. 8) can be within about 50%, about 40%, about 30%, about 25%, about 20%, about 15%, about 10%, about 7.5%, about 5%, about 4%, about 3%, about 2%, or about 1% of the lateral width of a portion of the suspended frame 136 in the active region 130 on the other side (e.g., the right side of FIG. 8), or any values or ranges therebetween, although other configurations are possible. In some embodiments, the first conductive material 166, the opening in the passivation layer 124, and/or the electrical interconnection between the upper electrode 118 and the first conductive layer 166 can be disposed laterally outside the piezoelectric layer 116 and/or laterally outside the active region 130. The upper electrode 118 can extend laterally further on one side (e.g., the left side of FIG. 8) than the other, such as to electrically couple with the first conductive layer 166. The smaller piezoelectric layer 116 of FIG. 8 can cutoff the active region 130 at that side to deemphasize the asymmetry of the longer electrode 118 on that side.

The BAW device can be a film bulk acoustic wave resonator (FBAR), as illustrated in FIGS. 2-4 and 8. A cavity 112 can be included, such as below the first or lower electrode 114. The cavity 112 can be filled with air, in some implementations. The cavity 112 can be defined by the geometry of the first electrode 114 and/or the substrate 110. The cavity 112 can be an acoustic reflector cavity. The cavity 112 can be separate from the gap 122 disclosed herein. The cavity 112 can be disposed below the lower electrode 114. The gap 122 can be disposed above a lower surface of the lower electrode 114, above the lower electrode 114, and/or above the piezoelectric layer 116.

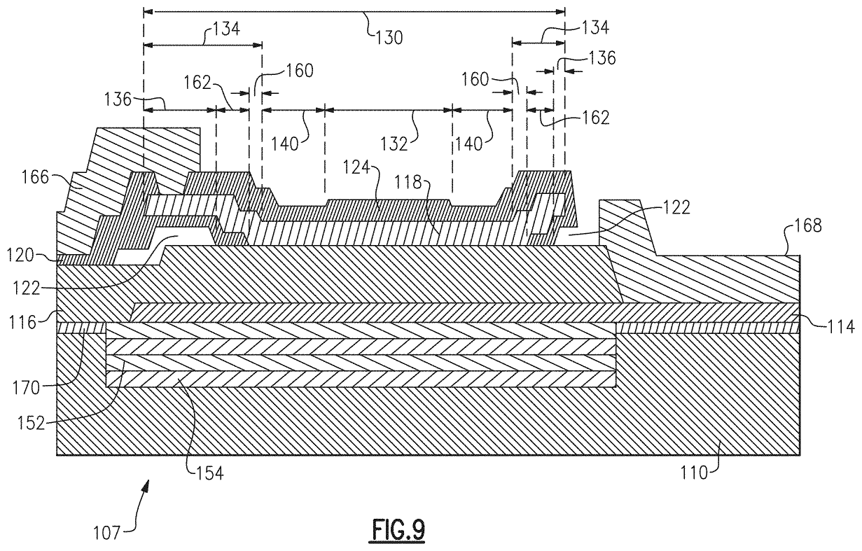

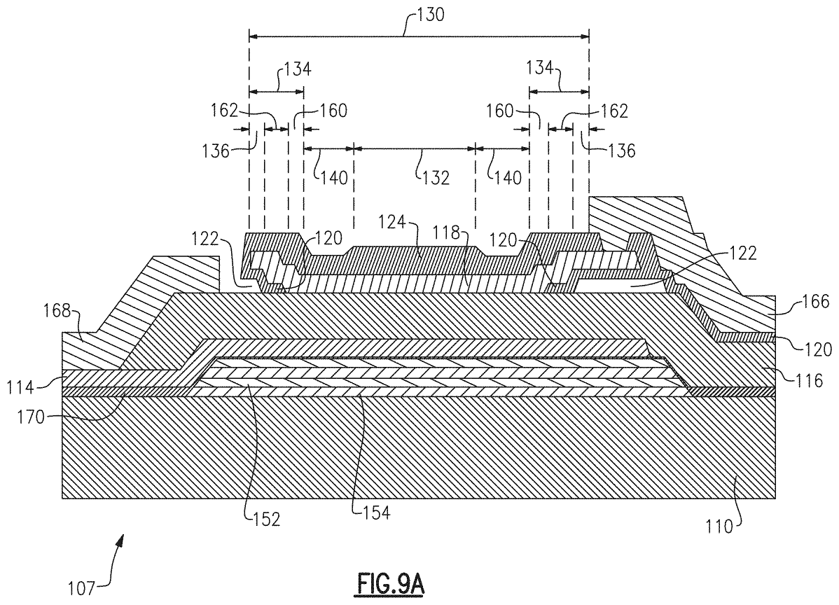

Although some of the BAW devices illustrated and described herein are FBAR devices, any suitable principles and advantages discussed herein can be applied to a solidly mounted resonator (SMR). FIG. 9 is a cross-sectional view of an example embodiment of a BAW device 107, which can be similar to the BAW device 101 of FIG. 3, except that the BAW device 107 is an SMR instead of an FBAR. In the BAW device 107 of FIG. 9, a solid acoustic mirror can be disposed between the first electrode 114 and a silicon substrate 110. The illustrated acoustic mirror includes acoustic Bragg reflectors. The illustrated acoustic Bragg reflectors include alternating low impedance layers 152 and high impedance layers 154. As an example, the Bragg reflectors can include alternating silicon dioxide layers as low impedance layers 152 and tungsten layers as high impedance layers 154, although other suitable materials could be used. The raised frame layer structure of the embodiment of FIG. 9 can have similar features and functionality to the raised frame or suspended frame structure in the embodiment of FIG. 3.

FIG. 10 is a cross-sectional view of an example embodiment of a BAW device 109, which can be similar to the BAW device 103 of FIG. 8, except that the BAW device 109 is an SMR instead of an FBAR. In the BAW device 109 of FIG. 10, a solid acoustic mirror can be disposed between the first electrode 114 and a silicon substrate 110. The illustrated acoustic mirror includes acoustic Bragg reflectors. The illustrated acoustic Bragg reflectors include alternating low impedance layers 152 and high impedance layers 154. As an example, the Bragg reflectors can include alternating silicon dioxide layers as low impedance layers 152 and tungsten layers as high impedance layers 154, although other suitable materials could be used. The raised frame layer structure of the embodiment of FIG. 10 can have similar features and functionality to the raised frame or suspended frame structure in the embodiment of FIG. 8. Any of the other embodiments disclosed herein can be an FBAR or SMR. For example, embodiments that include a cavity 112 can instead include Bragg reflectors, such as similar to FIGS. 9 and 10.

FIG. 11 is a cross-sectional view of an example embodiment of a BAW device 111, which can be similar to the other BAW devices disclosed herein, except that the BAW device 111 can include a raised frame layer 121 disposed over the upper electrode 118. The raised frame layer 121 can be a relatively high acoustic impedance material. The raised frame layer 121 can include a relatively high density material. For instance, the raised frame layer 121 can include molybdenum (Mo), tungsten (W), ruthenium (Ru), platinum (Pt), iridium (Ir), Ir/Pt, the like, or any suitable alloy of any of these materials. The raised frame layer 121 can be a metal layer. Alternatively, the raised frame layer 121 can be a suitable non-metal material with a relatively high density and/or acoustic impedance. The density and/or acoustic impedance of the raised frame layer 121 can be similar to or greater than the density and/or acoustic impedance of the lower electrode 114, of the upper electrode 118, or the piezoelectric layer 116.

In some instances, the raised frame structure 121 can be of the same material as the lower electrode 114 and/or the upper electrode 118 of the BAW device 111. In some implementations, the raised frame layer 121 can be adjacent to the upper electrode 118. The upper electrode 118 can have a substantially uniform thickness, although in some cases it may be angled (e.g., downward or toward the piezoelectric layer 116). The raised frame layer 121 can be a thickened region of the same material that makes up the upper electrode 118. The upper electrode 118 and the raised frame layer 121 can be formed by different processing steps, and in some cases the can be a resulting identifiable transition between the upper electrode 118 and the raised frame layer 121 of the same material, although some implementations may not have an identifiable transition between the upper electrode and the raised frame layer 121. The passivation layer 124 can be positioned over the upper electrode 118 and/or over the raised frame layer 121. The raised frame layer 121 can at least partially overlap the gap 122, such as in the active region 130. The raised frame layer 121 can be positioned over the upper electrode 118. In some embodiments, the BAW device 111 does not include the raised frame layer 120. The gap 122 can be formed between the piezoelectric layer 116 and the upper electrode 118. In some embodiments, the BAW device 111 can include a suspended frame 136 that is elevated by the gap 122.

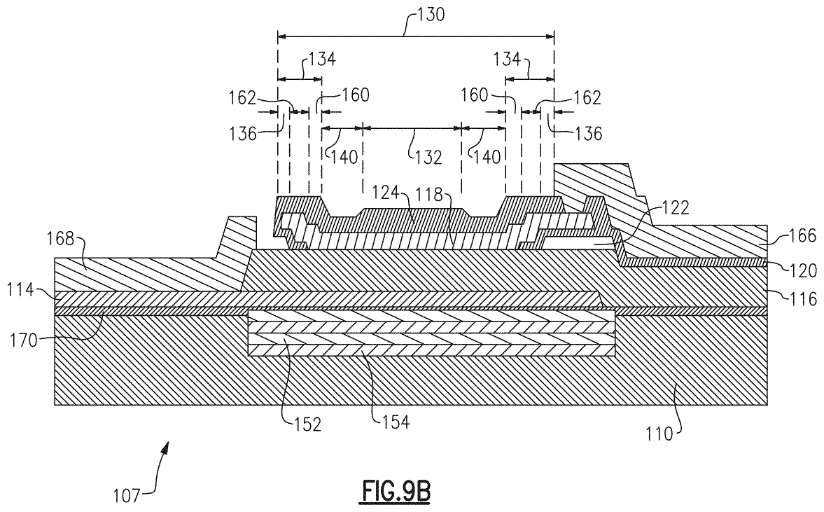

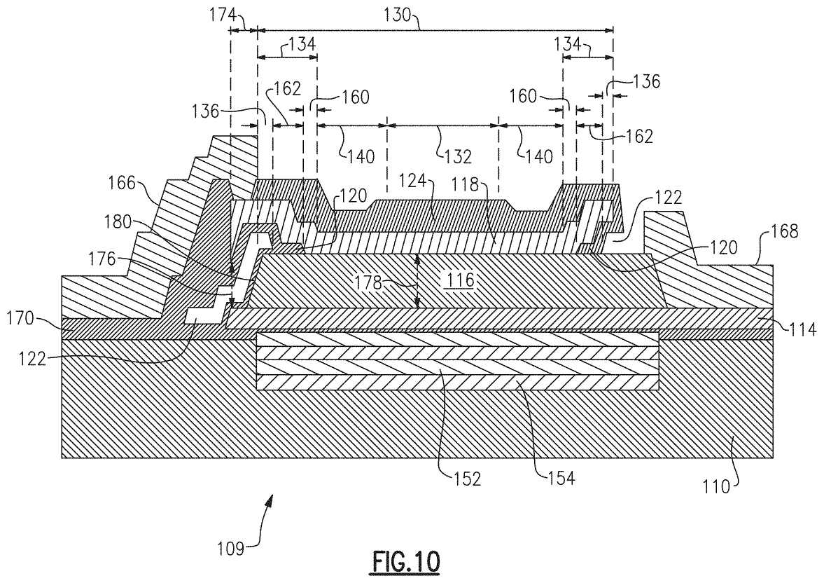

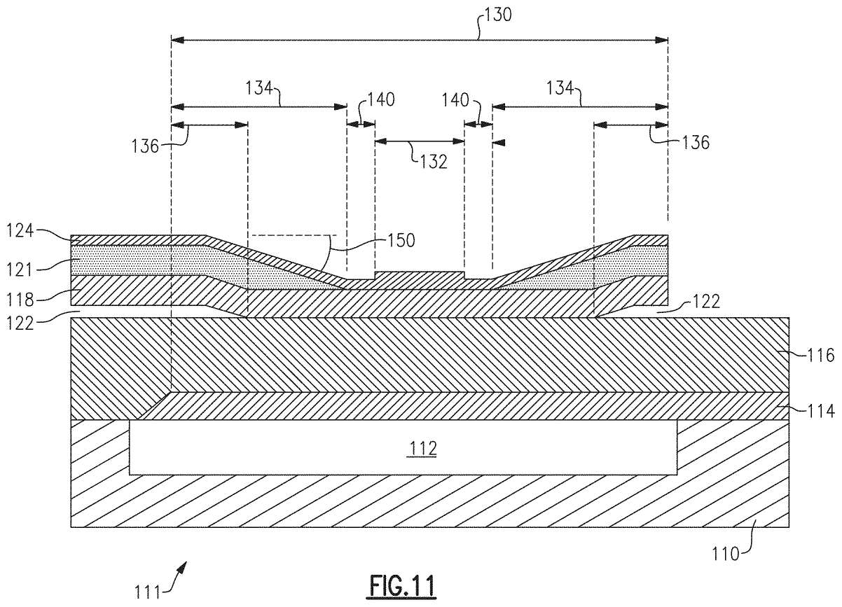

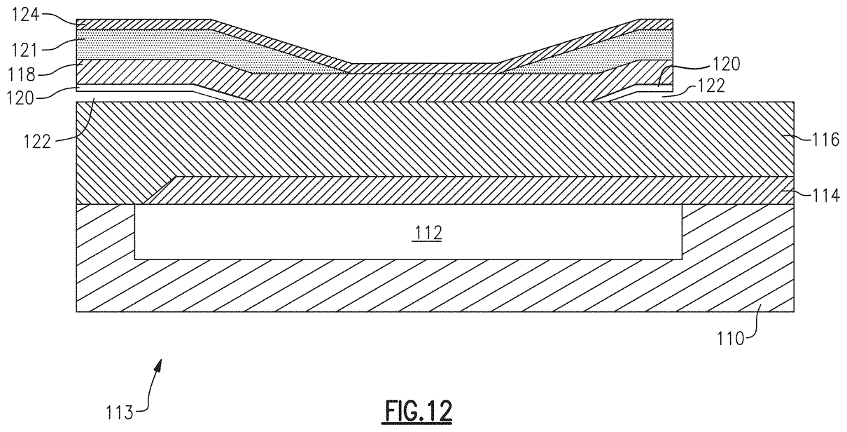

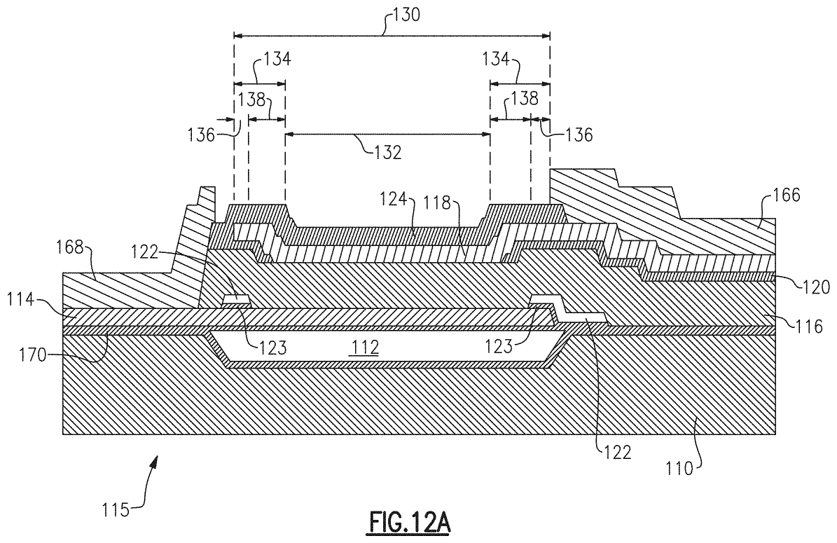

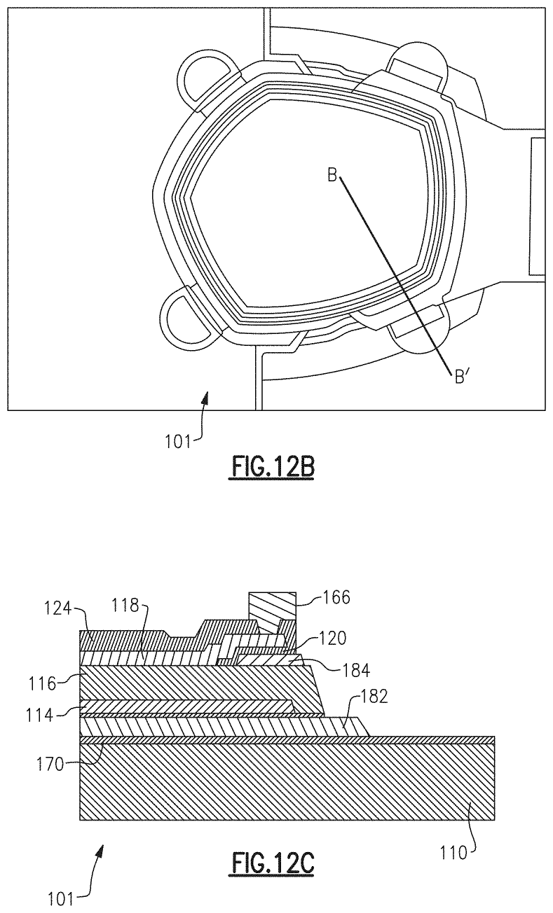

FIG. 12 is a cross-sectional view of an example embodiment of a BAW device 113, which can be similar to the other BAW devices disclosed herein, except that the BAW device 113 can have dual-layer raised frame structure, which can include a first raised frame layer 120 and a second raised frame layer 121. The density and/or acoustic impedance of the first raised frame layer 120 can be lower than the density and/or acoustic impedance of the lower electrode 114, of the upper electrode 118, of the piezoelectric layer 116, and/or of the second raised frame layer 121. The second raised frame layer 121 can at least partially overlap the first raised frame layer 120, such as in the active region 130 of the BAW device 113. The second raised frame layer 121 can be positioned over the upper electrode 118. The upper electrode 118 can be positioned between the first raised frame layer 120 and the second raised frame layer 121. The first raised frame layer 120, the upper electrode 118, and the second raised frame layer 121 can be disposed above the gap 122. The second raised frame layer 121 can be a relatively high acoustic impedance material. The second raised frame layer 121 can include a relatively high density material. For instance, the second raised frame layer 121 can include molybdenum (Mo), tungsten (W), ruthenium (Ru), platinum (Pt), iridium (Ir), the like, or any suitable alloy of any of these materials. The second raised frame layer 121 can be a metal layer. Alternatively, the second raised frame layer 121 can be a suitable non-metal material, such as having a relatively high density. The density and/or acoustic impedance of the second raised frame layer 121 can be similar to or greater than the density and/or acoustic impedance of the lower electrode 114, of the upper electrode 118, of the piezoelectric layer 116, and/or of the first raised frame layer 120 of the BAW device 113. In some instances, the second raised frame structure 121 can be of the same material as the lower electrode 114 and/or the upper electrode 118. In some implementations, the second raised frame layer 121 can be adjacent to the upper electrode 118. The upper electrode 118 can have a substantially uniform thickness, although in some cases it may be angled (e.g., downward or toward the piezoelectric layer 116). The second raised frame layer 121 can be a thickened region of the same material that makes up the upper electrode 118. The upper electrode 118 and the second raised frame layer 121 can be formed by different processing steps, and in some cases the can be a resulting identifiable transition between the upper electrode 118 and the second raised frame layer 121 of the same material, although some implementations may not have an identifiable transition between the upper electrode and the second raised frame layer 121. The passivation layer 124 can be positioned over the upper electrode 118 and/or over the second raised frame layer 121.

Many variations are possible. In some embodiments, the raised frame layer 120 and/or gap 122 can be in a different position from the embodiments illustrated herein. The raised frame layer 120 and/or the gap 122 can be positioned between the first or lower electrode 114 and the piezoelectric layer 116. FIG. 12A shows a cross-sectional view of an example embodiment of a bulk acoustic wave device 115. The BAW device 115 can be similar to the other embodiments disclosed herein, except as described. The gap 122 can be disposed below the piezoelectric layer 116. The gap 122 can be disposed between the piezoelectric layer 116 and the substrate 110, or between the piezoelectric layer 116 and the lower electrode 114. A suspended frame portion 136 can be positioned above the gap 122. An inner raised frame portion 138 can be disposed inward of the suspended frame portion 136, and can correspond to a portion that is elevated by the raised frame layer 120, but not positioned over the gap 122. The raised frame layer 120 can be disposed over the piezoelectric layer 116, such as between the piezo electric layer 116 and the upper electrode 118. In some embodiments, a second raised frame layer 123 can be disposed below the piezoelectric layer 116, such as between the piezoelectric layer 116 and the lower electrode 114 or the substrate 110. The second raised frame layer 123 can be silicon dioxide, or another oxide material, or some other insulating or low acoustic impedance material. The gap 122 can be disposed over the second raised frame layer 123. The second raised frame layer 123 can be between the gap 122 and the first or lower electrode 114. In some embodiments, the second raised frame layer 123 can be omitted. In some embodiments, the raised frame layer 120 can be omitted. For example, the layer 123 below the piezoelectric layer 116 can be the raised frame layer, and in some cases there may be no raised frame layer above the piezoelectric layer 116. In some embodiments, the raised frame layer 123 can extend inward beyond the gap 122. The raised frame layer 123 can be in physical contact with the piezoelectric layer 116 and the first electrode 114, such as at the inner raised frame portion 138. The raised frame layer 123 can be in contact with the lower electrode 114 and can be spaced apart from the piezoelectric layer 116 by the gap 122 (e.g., at the suspended frame portion 136). The raised frame layer 123 can be in contact with the piezoelectric layer 116 and spaced apart from the lower electrode 114 by the gap 122, such as at the suspended frame portion 136. The piezoelectric layer 116 can have a stepped cross-sectional shape due to the raised frame layer 123 and/or the gap 122. The piezoelectric layer 116 can have step(s) where the piezoelectric layer 116 is elevated by the raised frame layer 123 and/or the gap 122. In some embodiments, one of the raised frame layer 120 or the gap 122 can be between the piezoelectric layer 116 and the lower electrode 114 and the other of the gap 122 and the raised frame layer 120 can be between the piezoelectric layer 116 and the upper electrode 118.

Also, in the BAW device 113 of FIGS. 12 and 12A, the recessed frame region 140 is omitted. For example, the passivation layer 124 can have a substantially uniform thickness inside of the raised frame region 138 and/or the suspended frame region 136. In some embodiments, the middle portion or main acoustically active region of the BAW device can be the area inside of the raised frame region 138 and/or the suspended frame region 136. In some other embodiments, the passivation layer 124 can be omitted. In some embodiments, the BAW device of 113 can have a recessed frame region 140, similar to other embodiments disclosed herein.

The various features of the BAW devices of FIGS. 2-4 and 8-12 can be combined. For example, any of the BAW devices can be an SMR instead of an FBAR, or vice versa. Any of the BAW devices of FIGS. 2-4 and 8-12 can have the raised frame layer 120 and/or gap 122 disposed between the lower electrode 114 and the piezoelectric layer 116. Any of the BAW devices can have a raised frame layer 121 disposed above the upper electrode 118 (e.g., as shown in FIG. 11). Any of the BAW devices can include a multi-layered raised frame structure, such as having a first raised frame layer 120 and a second raised frame layer 121 (e.g., as shown in FIG. 12). Any of the BAW devices can omit the recessed frame region 140 (e.g., as shown FIG. 12) or can omit the passivation layer 124. A BAW device can include any combination of these features.

The BAW devices disclosed herein can be made using any suitable techniques or processes. In some cases, material or layers can be deposited by any suitable technique, and select portions of the deposited material can be removed, such as by etching, while other portions of the deposited material can be retained, such as by shielding the material from etching using a mask. Various other manufacturing processes could be used.

An example manufacturing process is described, but other variations are possible. In some embodiments, a substrate (e.g., substrate 110) can be provided, such as a silicon (Si) wafer. A passivation layer (e.g., oxide layer 170) can be formed (e.g., deposited) onto or over the substrate. The passivation layer can be silicon dioxide. A cavity sacrificial layer can be formed (e.g., deposited and patterned) onto or over the substrate or passivation layer (e.g., to form the shape of the cavity 112). A membrane layer can be formed (e.g., deposited) onto or over the cavity sacrificial layer. The membrane layer can be the same material as the passivation layer (e.g., silicon dioxide). A conductive layer (e.g., metal) can be formed (e.g., deposited and patterned) onto or over the substrate, the cavity sacrificial material, or the membrane, such as to provide the lower electrode 114. A piezoelectric layer 116 can be formed (e.g., deposited) onto or over the conductive layer of the lower electrode 114. A suspended frame sacrificial layer can be formed (e.g., deposited), such as onto or over the piezoelectric layer 116. The suspended frame sacrificial layer can be patterned to provide the shape of the gap(s) 122. A first raised frame layer can be formed (e.g., deposited and patterned) to provide the first raised frame layer 120. A conductive layer (e.g., metal) can be formed (e.g., deposited) onto or over the first raised frame layer 120 or the suspended frame sacrificial material, such as to form the upper electrode 118. In some embodiments, a second raised frame layer 121 can be formed (e.g., deposited and patterned), such as onto or over the upper electrode 118. The conductive layer can be formed (e.g., patterned) to provide the shape of the upper electrode 118. The piezoelectric material can be formed (e.g., patterned) to form the shape of the piezoelectric layer 116. A passivation layer 124 can be formed (e.g., deposited), such as onto or over the upper electrode 118 or second raised frame layer 121. In some embodiments, the passivation layer can be patterned to form the recessed frame region 140. In some embodiments, the passivation layer 124 can be formed (e.g., patterned) to provide an opening. A conductive (e.g., metal) layer can be formed (e.g., deposited and patterned) so that the conductive layer 166 extends into the opening in the passivation layer and contacts the upper electrode 118 or second raised frame layer 121. The conductive material can also form the second conductive layer 168 that has electrical contact with the lower electrode 114. In some embodiments, contacts (e.g., metal pads) can be formed, which can be configured to provide signals to and/or from the lower electrode 114 (e.g., through conductive layer 168) and the upper electrode (e.g., through conductive layer 166). The cavity sacrificial layer can be removed to form the cavity 112. The suspended frame sacrificial layer can be removed to form the gap(s) 122. In some embodiments, the cavity sacrificial layer and the suspended frame sacrificial layer can be removed together, such as during the same process step, or at the same time.

FIG. 12B shows a plan view of an example embodiment of a bulk acoustic device. FIG. 12C shows a cross-section view of the BAW device of FIG. 12B taken along the line from B to B′. The BAW device 101 can have a substrate 100, a passivation layer or oxide layer 170, a cavity sacrificial layer 182, a lower electrode layer 114, a piezoelectric layer 116, a suspended frame sacrificial layer 184, a raised frame layer 120, an upper electrode layer 118, a passivation layer 124, and/or a conductive layer 166. These layers can be deposited and/or patterned to form the shapes and configurations disclosed herein. At the cross-section shown in FIG. 12C, the cavity sacrificial layer 182 and the suspended frame sacrificial layer 184 can both be exposed, so that the sacrificial layers can be removed (e.g., by dry etching or wet etching, or any other suitable technique). Since both the cavity sacrificial layer 182 and the suspended frame sacrificial layer 184 are exposed, they can both be removed during the same processing step and/or at the same time. The cavity sacrificial layer 182 can extend into or laterally past a gap or space between the piezoelectric layer 116 and the substrate 110, in some embodiments. The suspended frame sacrificial layer 184 can extend into or laterally past a gap or space between the piezoelectric layer 116 and the raised frame layer 120.

The BAW resonators disclosed herein can be implemented in acoustic wave filters. In certain applications, the acoustic wave filters can be band pass filters arranged to pass a radio frequency band and attenuate frequencies outside of the radio frequency band. Two or more acoustic wave filters can be coupled together at a common node and arranged as a multiplexer, such as a duplexer.

FIG. 13 is a schematic diagram of an example of an acoustic wave ladder filter 220. The acoustic wave ladder filter 220 can be a transmit filter or a receive filter. The acoustic wave ladder filter 220 can be a band pass filter arranged to filter a radio frequency signal. The acoustic wave filter 220 can include series resonators R1, R3, R5, R7, and R9 and shunt resonators R2, R4, R6, and R8 coupled between a radio frequency input/output port RFI/O and an antenna port ANT. The radio frequency input/output port RFI/O can be a transmit port in a transmit filter or a receive port in a receive filter. One or more of the illustrated acoustic wave resonators can be a bulk acoustic wave resonator in accordance with any suitable principles and advantages discussed herein. An acoustic wave ladder filter can include any suitable number of series resonators and any suitable number of shunt resonators.

An acoustic wave filter can be arranged in any other suitable filter topology, such as a lattice topology or a hybrid ladder and lattice topology. A bulk acoustic wave resonator in accordance with any suitable principles and advantages disclosed herein can be implemented in a band pass filter. In some other applications, a bulk acoustic wave resonator in accordance with any suitable principles and advantages disclosed herein can be implemented in a band stop filter.

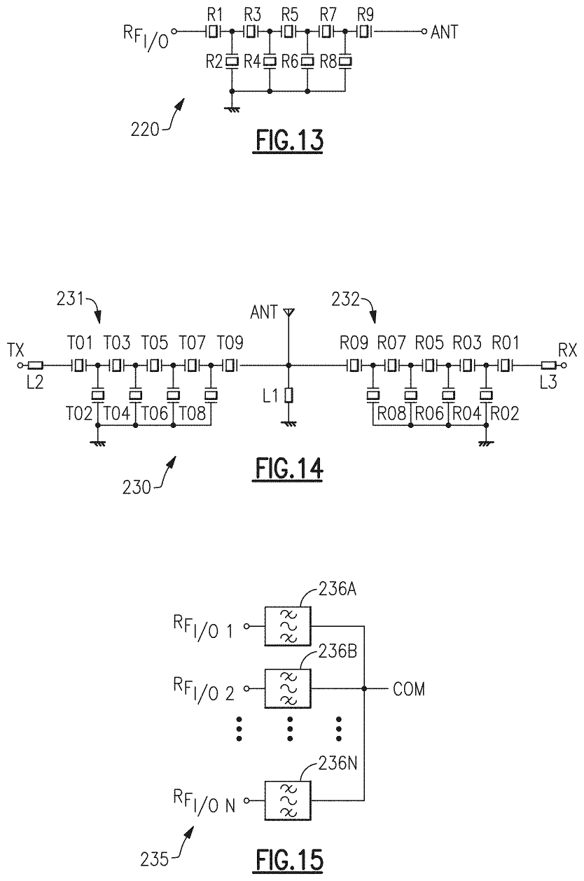

FIG. 14 is a schematic diagram of an example of a duplexer 230. The duplexer 230 can include a transmit filter 231 and a receive filter 232 coupled to each other at an antenna node ANT. A shunt inductor L1 can be connected to the antenna node ANT. The transmit filter 231 and the receive filter 232 can both be acoustic wave ladder filters in the duplexer 230.

The transmit filter 131 can filter a radio frequency signal and provide a filtered radio frequency signal to the antenna node ANT. A series inductor L2 can be coupled between a transmit input node TX and the acoustic wave resonators of the transmit filter 131. The illustrated transmit filter 131 can include acoustic wave resonators TO1 to T09. One or more of these resonators can be bulk acoustic wave resonator in accordance with any suitable principles and advantages disclosed herein. The illustrated receive filter can include acoustic wave resonators R01 to R09. One or more of these resonators can be a bulk acoustic wave resonator in accordance with any suitable principles and advantages disclosed herein. The receive filter can filter a radio frequency signal received at the antenna node ANT. A series inductor L3 can be coupled between the resonator and a receive output node RX. The receive output node RX of the receive filter provides a radio frequency receive signal.

FIG. 15 is a schematic diagram of a multiplexer 235 that includes an acoustic wave filter according to an embodiment. The multiplexer 235 can include a plurality of filters 236A to 236N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. Each of the illustrated filters 236A, 236B, and 236N can be coupled between the common node COM and a respective input/output node RFI/O1, RFI/O2, and RFI/ON.

In some instances, all filters of the multiplexer 235 can be receive filters. According to some other instances, all filters of the multiplexer 235 can be transmit filters. In various applications, the multiplexer 235 can include one or more transmit filters and one or more receive filters. Accordingly, the multiplexer 235 can include any suitable number of transmit filters and any suitable number of receive filters. Each of the illustrated filters can be band pass filters having different respective pass bands.

The multiplexer 235 is illustrated with hard multiplexing with the filters 236A to 236N having fixed connections to the common node COM. In some other applications, one or more of the filters of a multiplexer can be electrically connected to the common node by a respective switch. Any of such filters can include a bulk acoustic wave resonator according to any suitable principles and advantages disclosed herein.

A first filter 236A can be an acoustic wave filter having a first pass band and arranged to filter a radio frequency signal. The first filter 236A can include one or more bulk acoustic wave resonators according to any suitable principles and advantages disclosed herein. A second filter 236B has a second pass band. In some embodiments, a raised frame structure of one or more bulk acoustic wave resonators of the first filter 236A can move a raised frame mode of the one or more bulk acoustic wave resonators away from the second passband. This can increase a reflection coefficient (Gamma) of the first filter 236A in the pass band of the second filter 236B. The raised frame structure of the bulk acoustic wave resonator of the first filter 236A can also move the raised frame mode away from the passband of one or more other filters of the multiplexer 235.

In certain instances, the common node COM of the multiplexer 235 can be arranged to receive a carrier aggregation signal including at least a first carrier associated with the first passband of the first filter 236A and a second carrier associated with the second passband of the second filter 236B. A multi-layer raised frame structure of a bulk acoustic wave resonator of the first filter 236A can maintain and/or increase a reflection coefficient of the first filter 236A in the second passband of the second filter 236B that is associated with the second carrier of the carrier aggregation signal.

The filters 236B to 236N of the multiplexer 235 can include one or more acoustic wave filters, one or more acoustic wave filters that include at least one bulk acoustic wave resonator with a raised frame structure, one or more LC filters, one or more hybrid acoustic wave LC filters, or any suitable combination thereof.

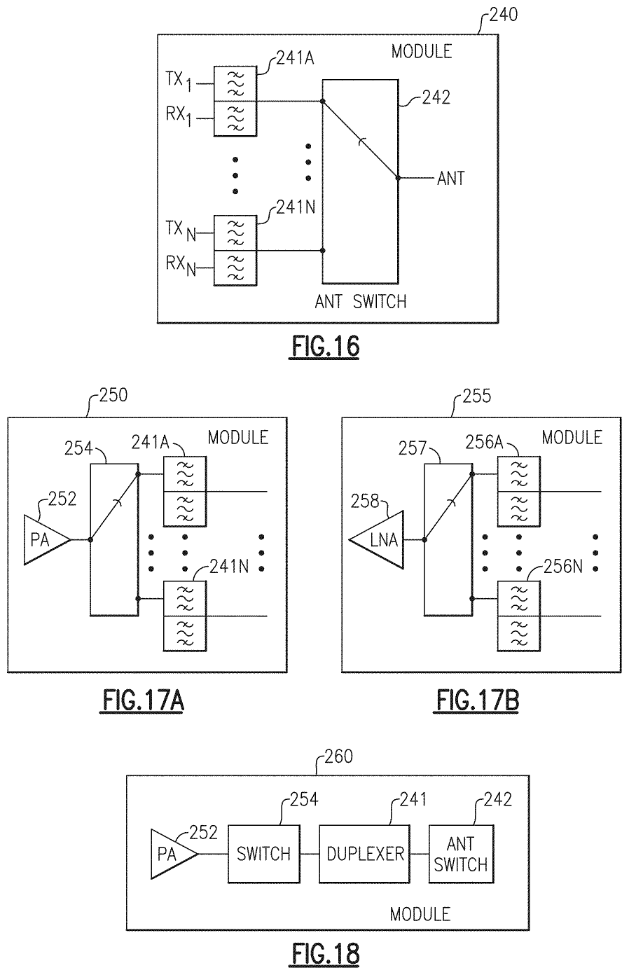

The raised frame bulk acoustic wave resonators disclosed herein can be implemented in a variety of packaged modules. Some example packaged modules will now be discussed in which any suitable principles and advantages of the bulk acoustic wave devices disclosed herein can be implemented. The example packaged modules can include a package that encloses the illustrated circuit elements. The illustrated circuit elements can be disposed on a common packaging substrate. The packaging substrate can be a laminate substrate, for example. FIGS. 16, 17A, 17B, and 18 are schematic block diagrams of illustrative packaged modules according to certain embodiments. Certain example packaged modules can include one or more radio frequency amplifiers, such as one or more power amplifiers and/or one or more low noise amplifiers. Any suitable combination of features of these modules can be implemented with each other. While duplexers are illustrated in the example packaged modules of FIGS. 16, 17A, and 18, any other suitable multiplexer that includes a plurality of acoustic wave filters coupled to a common node can be implemented instead of one or more duplexers. For example, a quadplexer can be implemented in certain applications. Alternatively or additionally, one or more filters of a packaged module can be arranged as a transmit filter or a receive filter that is not included in a multiplexer.

FIG. 16 is a schematic block diagram of an example module 240 that includes duplexers 241A to 241N and an antenna switch 242. One or more filters of the duplexers 241A to 241N can include any suitable number of multi-layer raised frame bulk acoustic wave resonators in accordance with any suitable principles and advantages discussed herein. Any suitable number of duplexers 241A to 241N can be implemented. The antenna switch 242 can have a number of throws corresponding to the number of duplexers 241A to 241N. The antenna switch 242 can electrically couple a selected duplexer to an antenna port of the module 240.

FIG. 17A is a schematic block diagram of an example module 250 that includes a power amplifier 252, a radio frequency switch 254, and duplexers 241A to 241N in accordance with one or more embodiments. The power amplifier 252 can amplify a radio frequency signal. The radio frequency switch 254 can be a multi-throw radio frequency switch. The radio frequency switch 254 can electrically couple an output of the power amplifier 252 to a selected transmit filter of the duplexers 241A to 241N. One or more filters of the duplexers 241A to 241N can include any suitable number of raised frame bulk acoustic wave resonators in accordance with any suitable principles and advantages discussed herein. Any suitable number of duplexers 241A to 241N can be implemented.

FIG. 17B is a schematic block diagram of an example module 255 that includes filters 256A to 256N, a radio frequency switch 257, and a low noise amplifier 258 according to one or more embodiments. One or more filters of the filters 256A to 256N can include any suitable number of raised frame bulk acoustic wave resonators in accordance with any suitable principles and advantages disclosed herein. Any suitable number of filters 256A to 256N can be implemented. The illustrated filters 256A to 256N can be receive filters. In some embodiments (not illustrated), one or more of the filters 256A to 256N can be included in a multiplexer that also includes a transmit filter. The radio frequency switch 257 can be a multi-throw radio frequency switch. The radio frequency switch 257 can electrically couple an output of a selected filter of filters 256A to 256N to the low noise amplifier 257. In some embodiments (not illustrated), a plurality of low noise amplifiers can be implemented. The module 255 can include diversity receive features in certain applications.

FIG. 18 is a schematic block diagram of an example module 260 that includes a power amplifier 252, a radio frequency switch 254, and a duplexer 241 that includes a raised frame bulk acoustic wave device in accordance with one or more embodiments, and an antenna switch 242. The module 260 can include elements of the module 240 and elements of the module 250.

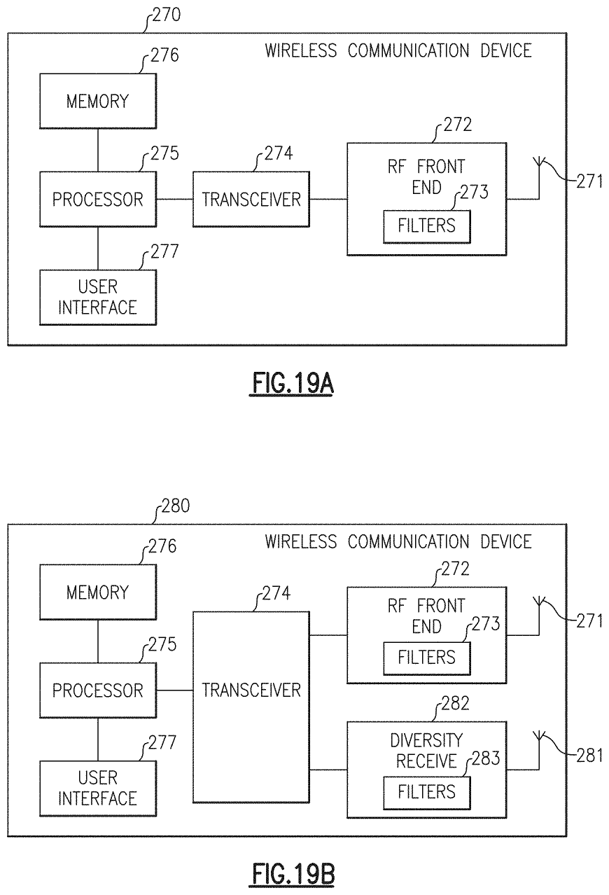

One or more filters with any suitable number of raised frame bulk acoustic devices can be implemented in a variety of wireless communication devices. FIG. 19A is a schematic block diagram of an example wireless communication device 270 that includes a filter 273 with one or more raised frame bulk acoustic wave resonators in accordance with any suitable principles and advantages disclosed herein. The wireless communication device 270 can be any suitable wireless communication device. For instance, a wireless communication device 270 can be a mobile phone, such as a smart phone. As illustrated, the wireless communication device 270 includes an antenna 271, a radio frequency (RF) front end 272 that includes filter 273, an RF transceiver 274, a processor 275, a memory 276, and a user interface 277. The antenna 271 can transmit RF signals provided by the RF front end 272. The antenna 271 can provide received RF signals to the RF front end 272 for processing.

The RF front end 272 can include one or more power amplifiers, one or more low noise amplifiers, RF switches, receive filters, transmit filters, duplex filters, filters of a multiplexer, filters of a diplexers or other frequency multiplexing circuit, or any suitable combination thereof. The RF front end 272 can transmit and receive RF signals associated with any suitable communication standards. Any of the multi-layer raised frame bulk acoustic wave resonators disclosed herein can be implemented in filters 273 of the RF front end 272.

The RF transceiver 274 can provide RF signals to the RF front end 272 for amplification and/or other processing. The RF transceiver 274 can also process an RF signal provided by a low noise amplifier of the RF front end 272. The RF transceiver 274 is in communication with the processor 275. The processor 275 can be a baseband processor. The processor 275 can provide any suitable base band processing functions for the wireless communication device 270. The memory 276 can be accessed by the processor 275. The memory 276 can store any suitable data for the wireless communication device 270. The processor 275 is also in communication with the user interface 277. The user interface 277 can be any suitable user interface, such as a display.

FIG. 19B is a schematic diagram of a wireless communication device 280 that includes filters 273 in a radio frequency front end 272 and second filters 283 in a diversity receive module 282. The wireless communication device 280 is like the wireless communication device 270 of FIG. 19A, except that the wireless communication device 280 also includes diversity receive features. As illustrated in FIG. 19B, the wireless communication device 280 can include a diversity antenna 281, a diversity module 282 configured to process signals received by the diversity antenna 281 and including second filters 283, and a transceiver 274 in communication with both the radio frequency front end 272 and the diversity receive module 282. One or more of the second filters 283 can include a bulk acoustic wave resonator with a multi-layer raised frame structure in accordance with any suitable principles and advantages disclosed herein.

Bulk acoustic wave devices disclosed herein can be included in a filter and/or a multiplexer arranged to filter a radio frequency signal in a fifth generation (5G) New Radio (NR) operating band within Frequency Range 1 (FR1). FR1 can from 410 megahertz (MHz) to 7.125 gigahertz (GHz), for example, as specified in a current 5G NR specification. A filter arranged to filter a radio frequency signal in a 5G NR FR1 operating band can include one or more bulk acoustic wave resonators be implemented in accordance with any suitable principles and advantages disclosed herein.

5G NR carrier aggregation specifications can present technical challenges. For example, 5G carrier aggregations can have wider bandwidth and/or channel spacing than fourth generation (4G) Long Term Evolution (LTE) carrier aggregations. Carrier aggregation bandwidth in certain 5G FR1 applications can be in a range from 120 MHz to 400 MHz, such as in a range from 120 MHz to 200 MHz. Carrier spacing in certain 5G FR1 applications can be up to 100 MHz. Bulk acoustic wave resonators with a raised frame structure as disclosed herein can achieve low insertion loss and low Gamma loss, in some embodiments. The frequency of a raised frame mode of such a bulk acoustic wave resonator can be moved significantly away from a resonant frequency of the bulk acoustic wave resonator. Accordingly, the raised frame mode can be outside of a carrier aggregation band even with the wider carrier aggregation bandwidth and/or channel spacing within FR1 in 5G specifications. This can reduce and/or eliminate Gamma degradation in an operating band of another carrier of a carrier aggregation. In some instances, Gamma can be increased in the operating band of the other carrier of the carrier aggregation.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, devices, modules, apparatus, methods, and systems described herein may be embodied in a variety of other forms. Furthermore, various omissions, substitutions and changes in the form of the resonators, devices, modules, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

The following is claimed:

1. A bulk acoustic wave device comprising:
a first electrode;
a second electrode; and
a piezoelectric layer between the first electrode and the second electrode, a portion of the first electrode extending laterally past an end of the piezoelectric layer, a portion of the second electrode extending laterally past the end of the piezoelectric layer, and a gap disposed between the portion of the first electrode and the portion of the second electrode.

2. The bulk acoustic wave device of claim 1 further comprising a suspended frame structure that includes a portion of the gap.

3. The bulk acoustic wave device of claim 1 further comprising a raised frame structure that includes a suspended frame portion that is suspended over a portion of the gap and an inner raised frame portion that is laterally inward of the suspended frame portion.

4. The bulk acoustic wave device of claim 3 wherein the raised frame structure includes a raised frame layer between the first electrode and the second electrode, the inner raised frame portion includes a first portion of the raised frame layer that is not over the gap, the suspended frame portion includes a second portion of the raised frame layer that extends over the gap.

5. The bulk acoustic wave device of claim 4 wherein the raised frame layer has a lower acoustic impedance than at least one of the first electrode, the second electrode, and the piezoelectric layer.

6. The bulk acoustic wave device of claim 3 wherein the suspended frame portion has a height that is greater than the inner raised frame portion.

7. The bulk acoustic wave device of claim 1 wherein a distance between the portion of the first electrode that extends laterally past the end of the piezoelectric layer and the portion of the second electrode that extends laterally past the end of the piezoelectric layer is less than a thickness of the piezoelectric layer.

8. The bulk acoustic wave device of claim 1 wherein a first portion of the gap extends over a portion of the top of the piezoelectric layer, and a second portion of the gap extends along a lateral end of the piezoelectric layer, and a third portion of the gap extends lower than a bottom of the piezoelectric layer.

9. The bulk acoustic wave device of claim 1 wherein a first portion of the gap is between the piezoelectric layer and the second electrode, and a second portion of the gap extends laterally past the end of the piezoelectric layer.

10. The bulk acoustic wave device of claim 1 wherein the second electrode includes a first portion that extends along an upper surface of the piezoelectric layer, a second portion that extends away from the first electrode, and a third portion that extends past the upper surface of the piezoelectric layer and towards the first electrode.

11. The bulk acoustic wave device of claim 1 further comprising a passivation layer over the first electrode, the second electrode, and the piezoelectric layer.

12. The bulk acoustic wave device of claim 11 further comprising a conductive layer disposed over a portion of the passivation layer, a portion of the conductive layer extending into an opening in the passivation layer to electrically contact the second electrode.

13. The bulk acoustic wave device of claim 12 wherein the opening in the passivation layer is directly over the gap.

14. A bulk acoustic wave device comprising:
a first electrode;
a second electrode;
a piezoelectric layer between the first electrode and the second electrode;
a gap between the first electrode and the second electrode;
a passivation layer, the second electrode between the piezoelectric layer and the passivation layer; and
a conductive layer, the passivation layer between a first portion of the conductive layer and the second electrode, a second portion of the conductive layer extending into an opening in the passivation layer to electrically contact the second electrode, wherein the opening in the passivation layer is disposed directly above the gap between the first electrode and the second electrode.

15. The bulk acoustic wave device of claim 14 wherein the opening in the passivation layer is disposed directly above the first electrode, the piezoelectric layer, and the second electrode.

16. The bulk acoustic wave device of claim 14 comprising an active region where the piezoelectric layer overlaps the first electrode and the second electrode, an end of the upper electrode defining a first end of the active region, and an end of the piezoelectric layer defining a second end of the active region opposite the first end.

17. The bulk acoustic wave device of claim 14 further comprising a suspended frame structure that includes a portion of the gap.

18. The bulk acoustic wave device of claim 14 further comprising a raised frame structure that includes a suspended frame portion that is suspended over a portion of the gap and an inner raised frame portion that is laterally inward of the suspended frame portion.

19. The bulk acoustic wave device of claim 18 wherein the raised frame structure includes a raised frame layer between the first electrode and the second electrode, the inner raised frame portion includes a first portion of the raised frame layer that is not over the gap, the suspended frame portion includes a second portion of the raised frame layer that extends over the gap.

20. The bulk acoustic wave device of claim 19 wherein the raised frame layer has a lower acoustic impedance than at least one of the first electrode, the second electrode, and the piezoelectric layer.

21. The bulk acoustic wave device of claim 18 wherein the suspended frame portion has a height that is greater than the inner raised frame portion.

22. The bulk acoustic wave device of claim 14 wherein a portion of the first electrode extends laterally past an end of the piezoelectric layer, a portion of the second electrode extends laterally past the end of the piezoelectric layer, and the gap is disposed between the portion of the first electrode and the portion of the second electrode.

23. The bulk acoustic wave device of claim 22 wherein a distance between the portion of the first electrode that extends laterally past the end of the piezoelectric layer and the portion of the second electrode that extends laterally past the end of the piezoelectric layer is less than a thickness of the piezoelectric layer.

24. The bulk acoustic wave device of claim 22 wherein a first portion of the gap extends over a portion of the top of the piezoelectric layer, and a second portion of the gap extends along a lateral end of the piezoelectric layer, and a third portion of the gap extends lower than a bottom of the piezoelectric layer.

25. The bulk acoustic wave device of claim 22 wherein a first portion of the gap is between the piezoelectric layer and the second electrode, and a second portion of the gap extends laterally past the end of the piezoelectric layer.

26. The bulk acoustic wave device of claim 14 wherein the second electrode includes a first portion that extends along an upper surface of the piezoelectric layer, a second portion that extends away from the first electrode, and a third portion that extends past the upper surface of the piezoelectric layer and towards the first electrode.
